(19) United States
(12) Patent Application Publication
(10) Pub. No.: US 2018/0013003 A1
(43) Pub. Date: Jan. 11, 2018

(54) SEMICONDUCTOR DEVICE

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd.

(21) Appl. No.: 15/642,641

(22) Filed: Jul. 6, 2017

(30) Foreign Application Priority Data
Jul. 11, 2016 (JP) 2016-137191

(51) Int. Cl. H01L 29/786; H01L 29/24

(52) U.S. Cl. CPC H01L 29/7869; H01L 29/24; H01L 29/78648

(57) ABSTRACT

A transistor including a metal oxide and having a high field-effect mobility is provided. A highly reliable display device including the transistor is provided. At least two or more layers of a metal oxide layer having a first bandgap and a metal oxide layer having a second bandgap are alternately stacked. A difference between the first bandgap and the second bandgap is preferably 0.3 eV or more, further preferably 0.4 eV or more. Carriers flow owing to an In oxide, an In-Zn oxide, or an In—Ti—Zn oxide having the second bandgap, i.e., a narrow bandgap. At that time, carriers overflow into an In—Ti—Ga—Zn oxide having the first bandgap, i.e., a wide bandgap, from the oxide having the second bandgap.

### BACKGROUND OF THE INVENTION

### 1. Field of the Invention

An embodiment of the present invention relates to a semiconductor device including a metal oxide layer and a method for manufacturing the semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. One embodiment of the present invention particularly relates to a metal oxide or a manufacturing method of the metal oxide. One embodiment of the present invention relates to a semiconductor device, a display device, a liquid crystal display device, a light-emitting device, a power storage device, a memory device, a driving method thereof, or a manufacturing method thereof

In this specification and the like, the term “semiconductor device” means all devices which can operate by utilizing semiconductor characteristics. Semiconductor elements such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may have a semiconductor device.

### 2. Description of the Related Art

As a semiconductor material that can be applied to a transistor, an oxide has been attracting attention. For example, Patent Document 1 discloses a field-effect transistor containing an amorphous oxide which is any of In—Zn—Ga—O-based, In—Zn—Ga—Mg—O-based, In—Zn—O-based, In—Sn—O-based, In—O-based, In—Ga—O-based, and Sn—In—Zn—O-based oxides.

Non-Patent Document 1 discusses a structure including a metal oxide with two stacked layers of an In—Zn—O-based oxide and an In—Ga—Zn—O-based oxide as an active layer of a transistor.

### REFERENCES

[Patent Document 1] Japanese Patent No. 5118810

[Non-Patent Document 1] John F. Wager, “Oxide TFTs: A Progress Report,” Information Display 1/16, SID 2016, January/February 2016, Vol. 32, No. 1, pp. 16-21

### SUMMARY OF THE INVENTION

An object of one embodiment of the present invention is to provide a semiconductor device having favorable electrical characteristics. Another object of one embodiment of the present invention is to provide a semiconductor device which can be miniaturized or highly integrated. Another object of one embodiment of the present invention is to provide a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention includes a structure in which metal oxide layers with different bandgaps are alternately stacked. A first metal oxide layer whose conduction band minimum is at a high energy level and a second metal oxide layer whose conduction band minimum is at a lower energy level than the conduction band minimum of the first metal oxide layer are alternately stacked, whereby a high on-state current in the on state of a transistor and a low off-state current in the off state of the transistor can be achieved.

In addition to the above structure, side surfaces of the metal oxide layers are in direct contact with a source region or a drain region (or a source electrode or a drain electrode) to decrease contact resistance, whereby the transistor can achieve high performance. Details thereof are as follows.

One embodiment of the present invention is a semiconductor device which includes a transistor including a first metal oxide layer whose conduction band minimum is at a high energy level, a second metal oxide layer, and a third metal oxide layer, the second metal oxide layer having a conduction band minimum at a lower energy level than the conduction band minimum of the first metal oxide layer and a conduction band minimum of the third metal oxide layer. The first metal oxide layer, the second metal oxide layer, and the third metal oxide layer are stacked. The second metal oxide layer is provided between the first metal oxide layer and the third metal oxide layer. A side surface of the second metal oxide layer is in contact with a source electrode or a drain electrode.

In the above structure, the first metal oxide layer and the third metal oxide layer may contain an M1 oxide (M1 is one kind or a plurality of kinds selected from Al, Ga, Si, Mg, Zr, Be, and B), an In-M1-Zn oxide, or an In-M1-M2-Zn oxide (M2 is one kind or a plurality of kinds selected from Ti, Ge, Sn, V, Ni, Mo, W, and Ta). M1 is preferably Ga.

The first metal oxide layer and the third metal oxide layer are formed using oxygen or a mixed gas of oxygen and a rare gas as a sputtering gas. The flow ratio of oxygen in the sputtering gas for forming the metal oxide layers is preferably 70% or more, further preferably 80% or more, still further preferably 100%. By increasing the proportion (flow ratio) of oxygen in the sputtering gas, the insulating property of the metal oxide layer can be increased.

Furthermore, an Al oxide or a Si oxide, which is the M1 oxide and can be used for the first metal oxide layer and the third metal oxide layer, may be replaced with a nitride. Specifically, the M1 oxide may be replaced with an aluminum nitride or a silicon nitride. Note that in this specification and the like, a metal oxide including nitrogen is also called a metal oxide in some cases. Moreover, a metal oxide including nitrogen may be called a metal oxynitride.

The thickness of each of the first metal oxide layer and the third metal oxide layer may be more than or equal to 0.1 nm and less than 30 nm, preferably more than or equal to 0.1 nm and less than or equal to 10 nm, further preferably more than or equal to 0.1 nm and less than or equal to 3 nm.

In the above structure, the second metal oxide layer may contain an In oxide, an In—Zn oxide, an In-M2 oxide, or an In-M2-Zn oxide. M2 is preferably Ti or Ge. A Ta oxide, which is the M2 oxide, may be replaced with a nitride. Specifically, the M2 oxide may be replaced with a tantalum nitride.

The thickness of the second metal oxide layer may be more than or equal to 0.1 nm and less than 30 nm, preferably more than or equal to 0.1 nm and less than or equal to 10 nm, further preferably more than or equal to 0.1 nm and less than or equal to 3 nm.

The total number n of stacked layers (n is greater than or equal to 3, preferably greater than or equal to 3 and less than or equal to 11) may be increased.

FIG. 1 illustrates an example of a cross section of a structure including a total of five layers, i.e., three metal oxide layers 116bw having a first bandgap (wide bandgap) and two metal oxide layers 116bn having a second bandgap (narrow bandgap).

FIG. 2A is an example of a band diagram of the stacked structure of the metal oxide layers along X-X′ section in FIG. 1.

The band of an actual stacked-layer structure is not discontinuous and changes continuously as illustrated in FIG. 2B because, in a junction portion of the metal oxide layer 116bw having the first bandgap and the metal oxide layer 116bn having the second bandgap, there is a fluctuation in aggregated form or composition of the metal oxide layers or part of the metal oxide layer 116bw having the first bandgap is included in the metal oxide layer 116bn having the second bandgap, in some cases.

In a transistor having such a stacked-layer structure in a channel formation region, the metal oxide layer 116bw having the first bandgap and the metal oxide layer 116bn having the second bandgap interact with each other electrically. Therefore, when a potential at which the transistor is turned on is applied to a conductor 114 having a function of a gate electrode, electrons flow in the metal oxide layer 116bn having the second bandgap with the conduction band minimum (Ec edge) at a low energy level and serving as a main conduction path, and at the same time, electrons also flow in the metal oxide layer 116bw having the first bandgap. This is because the Ec of the metal oxide layer 116bn having the second bandgap becomes significantly lower than the Ec of the metal oxide layer 116bw having the first bandgap. Thus, high current drive capability in the on state of the transistor, i.e., high on-state current and high field-effect mobility, can be obtained.

For the metal oxide layer 116bn having the second bandgap, a metal oxide which contains an indium zinc oxide as a main component and has high mobility is preferably used, for example. The metal oxide layer 116bn may be degenerate.

For the metal oxide layer 116bw having the first bandgap, a metal oxide which contains an indium gallium zinc oxide as a main component is preferably used, for example.

When a voltage lower than a threshold voltage is applied to the conductor 114 having a function of a gate electrode, the metal oxide layer 116bw having the first bandgap serves as a dielectric (an oxide having an insulating property), and a conduction path in the metal oxide layer 116bw is therefore blocked. The metal oxide layer 116bn having the second bandgap is in contact with the upper and lower metal oxide layers 116bw having the first bandgap. The metal oxide layers 116bw having the first bandgap electrically interact with each other and also with the metal oxide layer 116bn having the second bandgap, and thus, even the conduction path in the metal oxide layer 116bn having the second bandgap is blocked. This is because the Ec of the metal oxide layers 116bw having the first bandgap becomes significantly higher than the Ec of the metal oxide layer 116bn having the second bandgap. Accordingly, all the stacked metal oxide layers 116b are brought into a non-conductive state, and the transistor is turned off.

Next, the measurement of the Ec of the metal oxide layers used in this transistor will be described. FIG. 3 illustrates an example of energy bands of an oxide used in the transistor. As illustrated in FIG. 3, the Ec can be obtained from an ionization potential (or ionization energy) Ip, which is an energy difference between the vacuum level and the valence band maximum, and from a bandgap Eg. The bandgap Eg can be measured using a spectroscopic ellipsometer (UT-300 manufactured by HORIBA Jobin Yvon SAS). The ionization potential Ip can be measured using an ultraviolet photoelectron spectroscopy (UPS) device (VersaProbe manufactured by ULVAC-PHI, Inc.).

Another embodiment disclosed in this specification is a semiconductor device which includes a first metal oxide layer whose conduction band minimum is at a high energy level, a second metal oxide layer whose conduction band minimum is at a lower energy level than the conduction band minimum of the first metal oxide layer, a third metal oxide layer whose conduction band minimum is at an energy level higher than the conduction band minimum of the second metal oxide layer and lower than the conduction band minimum of the first metal oxide layer, a fourth metal oxide layer whose conduction band minimum is at a lower energy level than the conduction band minimum of the third metal oxide layer, and a fifth metal oxide layer whose conduction band minimum is at a high energy level.

In the above embodiment, the third metal oxide layer contains a material having an energy band different from those of the first metal oxide layer and the second metal oxide layer. Specifically, a material whose conduction band minimum is at an energy level higher than that of the second metal oxide layer and lower than that of the first metal oxide layer is selected as appropriate for the third metal oxide layer. Further, each of the second metal oxide layer, the third metal oxide layer, and the fourth metal oxide layer has a conduction band minimum lower than that of each of the first metal oxide layer and the fifth metal oxide layer.

In the above embodiment, a material of the fourth metal oxide layer is selected as appropriate from the above-described materials of the second metal oxide layer, and may be the same as or different from that of the second metal oxide layer. In the case of using the same material, the same sputtering target can be used, which is an advantage in productivity.

In the above embodiment, a material of the fifth metal oxide layer is selected as appropriate from the above-described materials of the first metal oxide layer, and may be the same as or different from that of the first metal oxide layer. In the case of using the same material, the same sputtering target can be used, which is an advantage in productivity.

Note that the threshold voltage of the transistor can be changed by introduction of an impurity element after the formation of the first metal oxide layer, the second metal oxide layer, the third metal oxide layer, the fourth metal oxide layer, or the fifth metal oxide layer. The impurity element can be introduced by an ion implantation method, an ion doping method, a plasma immersion ion implantation method, plasma treatment using a gas containing the impurity element, or the like.

In the above embodiment, another feature is a structure in which the second metal oxide layer is surrounded by a gate electrode, and another feature is to further include a first gate electrode, a second gate electrode, and seven or more metal oxide layers between the first gate electrode and the second gate electrode.

In the transistor of one embodiment of the present invention, the second gate electrode has a function of surrounding the second metal oxide layer electrically (or by an electric field) by covering also side surfaces thereof in a cross section in a channel width direction. With this structure, the on-state current of the transistor can be increased. Such a structure of the transistor is referred to as a surrounded channel (s-channel) structure. Note that in the s-channel structure, current flows in the whole (bulk) of the second metal oxide layer. Specifically, in the case of an n-channel transistor, that is, an accumulation-type transistor, bulk current flows when the impurity density (Nd) in a channel formation region is lower than or equal to 1E15 cm⁻³. Even in the case of a p-channel transistor, that is, an inversion-type transistor, bulk current flows when the impurity density (Nd) is lower than or equal to 1E15 cm³. Since current flows in an inner part of the second metal oxide layer, the current is hardly affected by interface scattering, and high on-state current can be obtained. Note that the on-state current can be improved by increasing the number of stacked metal oxide layers or by increasing the thickness thereof. In addition, with the s-channel structure, an excellent S value can be obtained. The relationship between the drain current and the gate voltage at around Vin or lower is also referred to as subthreshold characteristics, which are important to determine the performance of the transistor as a switching element. As a constant representing the subthreshold characteristics, a subthreshold swing (hereinafter abbreviated to an S value) is used. As the S value becomes smaller, the transistor can operate at higher speed with lower power consumption.

In a semiconductor device, a transistor including stacked metal oxide layers and having a high on-state current can be provided. A transistor including stacked metal oxide layers and having a low off-state current can be provided. A semiconductor device with low power consumption can be provided.

A novel semiconductor device can be provided. A module including the semiconductor device can be provided. An electronic device including the semiconductor device or the module can be provided.

### BRIEF DESCRIPTION OF THE DRAWINGS

FIG. 1 is a conceptual diagram of a stacked structure of metal oxide layers which illustrates one embodiment of the present invention.

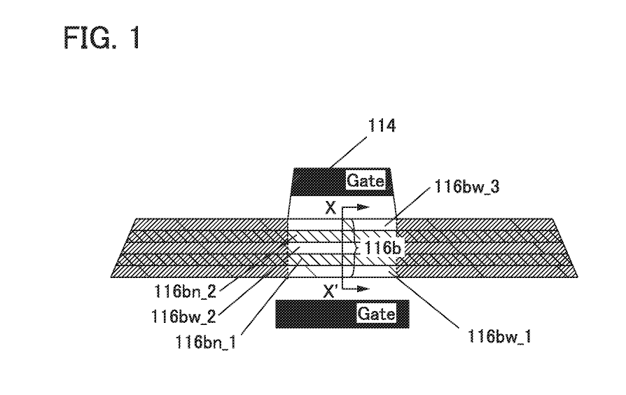

FIGS. 2A and 2B area band diagrams of a stacked structure of metal oxide layers of one embodiment of the present invention.

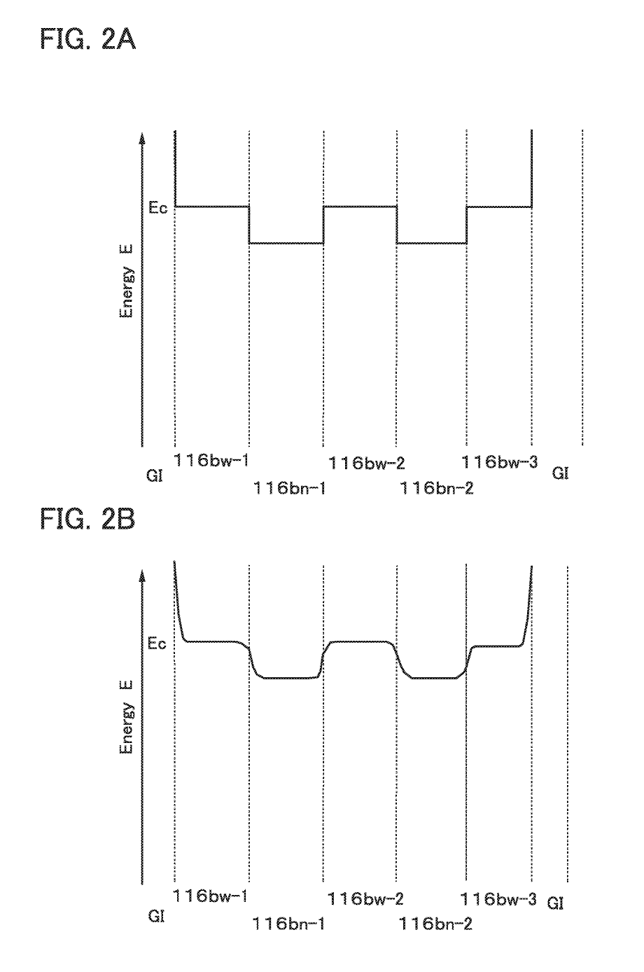

FIG. 3 illustrates a band structure of an oxide.

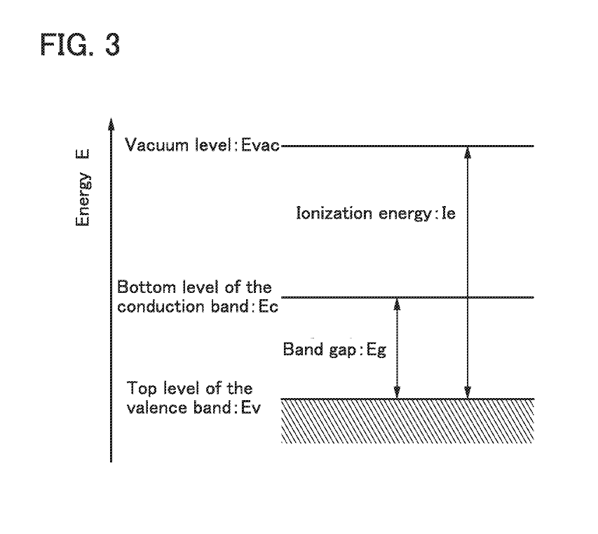

FIGS. 4A to 4D are a top view, cross-sectional views, and an enlarged cross-sectional view illustrating an embodiment of a semiconductor device.

FIGS. 5A to 5D are cross-sectional views illustrating an example of a process for manufacturing a semiconductor device.

FIGS. 6A to 6C are cross-sectional views illustrating an example of a process for manufacturing a semiconductor device.

FIGS. 7A to 7C are cross-sectional views illustrating an example of a process for manufacturing a semiconductor device.

FIG. 8 illustrates an example of a band structure.

FIGS. 9A to 9D are a top view, cross-sectional views, and an enlarged cross-sectional view illustrating one embodiment of a semiconductor device.

FIG. 10 illustrates an example of a band structure.

FIGS. 11A to 11D are a top view, cross-sectional views, and an enlarged cross-sectional view illustrating one embodiment of a semiconductor device.

FIG. 12 is a block diagram illustrating a display device.

FIG. 13 is a circuit diagram illustrating a pixel circuit.

FIGS. 14A and 14B are schematic views each illustrating a display region of a display element.

FIGS. 15A and 15B are top views illustrating a display device and a pixel circuit.

FIG. 16 is a cross-sectional view illustrating a display device.

FIG. 17 is a cross-sectional view illustrating a display device.

FIG. 18 is a cross-sectional view illustrating a display device.

FIGS. 19A and 19B illustrate a structural example of a display module.

FIGS. 20A to 20C illustrate examples of electronic devices.

### DETAILED DESCRIPTION OF THE INVENTION

Embodiments of the present invention will be described in detail below with reference to the drawings. However, the present invention is not limited to the description below, and it is easily understood by those skilled in the art that modes and details disclosed herein can be modified in various ways. Furthermore, the present invention is not construed as being limited to the description of the embodiments.

In this specification and the like, a transistor is an element having at least three terminals of a gate, a drain, and a source. The transistor includes a channel region between the drain (a drain terminal, a drain region, or a drain electrode) and the source (a source terminal, a source region, or a source electrode) and current can flow through the drain, the channel region, and the source. Note that in this specification and the like, a channel region refers to a region through which current mainly flows.

Functions of a source and a drain are sometimes replaced with each other when a transistor of opposite polarity is used or when the direction of current flow is changed in circuit operation, for example. Therefore, the terms “source” and “drain” can be replaced with each other in this specification and the like.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including a metal oxide or an oxide semiconductor.

### Embodiment 1

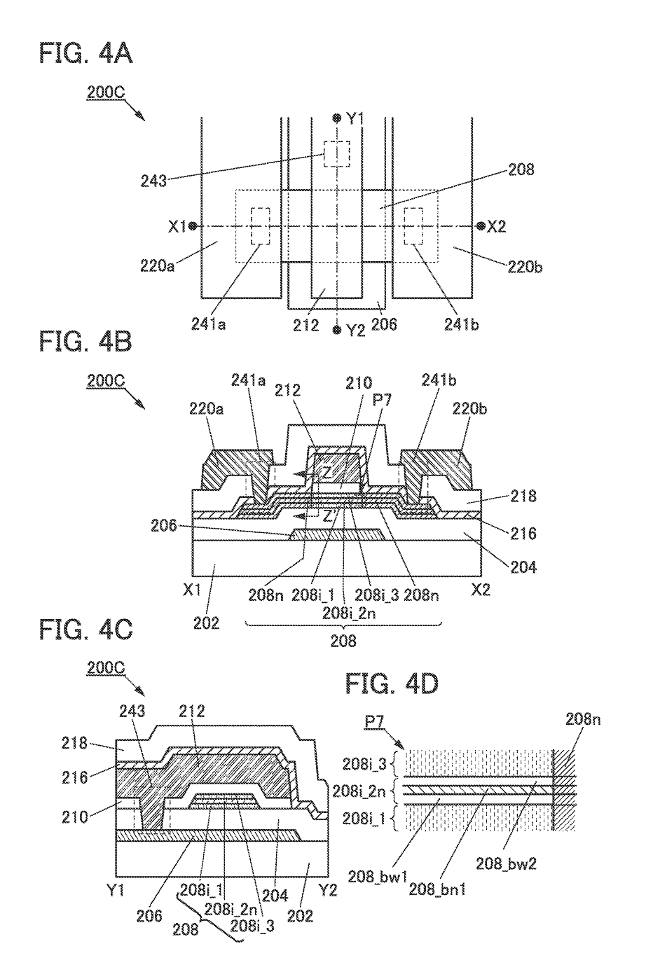

In this embodiment, a semiconductor device including a metal oxide of one embodiment of the present invention, and a manufacturing method of the semiconductor device will be described with reference to FIGS. 4A to 4D, FIGS. 5A to 5D, FIGS. 6A to 6C, and FIGS. 7A to 7C.

FIG. 4A is a top view of a transistor 200C that is a semiconductor device of one embodiment of the present invention. FIG. 4B is a cross-sectional view taken along a dashed-dotted line X1-X2 in FIG. 4A, and FIG. 4C is a cross-sectional view taken along a dashed-dotted line Y1-Y2 in FIG. 4A. FIG. 4D is an enlarged cross-sectional view of a region P7 in FIG. 4B.

Note that in FIG. 4A, some components of the transistor 200C (e.g., an insulating film serving as a gate insulating film) are not illustrated to avoid complexity. Furthermore, the direction of the dashed-dotted line X1-X2 may be referred to as a channel length direction, and the direction of the dashed-dotted line Y1-Y2 may be referred to as a channel width direction. As in FIG. 4A, some components are not illustrated in some cases in top views of transistors described below.

The transistor 200C illustrated in FIGS. 4A to 4C has what is called a top-gate structure.

The transistor 200C includes a conductive film 206 over a substrate 202, an insulating film 204 over the substrate 202 and the conductive film 206, a metal oxide 208 over the insulating film 204, an insulating film 210 over the metal oxide 208, a conductive film 212 over the insulating film 210, and an insulating film 216 over the insulating film 204, the metal oxide 208, and the conductive film 212.

The transistor 200C illustrated in FIGS. 4A to 4C has a multilayer structure of metal oxide layers. Specifically, the metal oxide 208 of the transistor 200C includes a region 208i_1, a region 208i_2n over the region 208i_, a region 208i_3 over the region 208i_2n, and regions 208n overlapping with the insulating film 216. The regions 208n can also be referred to as source or drain regions.

As illustrated in the region P7 in FIG. 4D, the region 208i_2n is a stack of three layers in the example described here. In the region 208i_2n of the metal oxide 208, a first metal oxide layer 208_bw1, a second metal oxide layer 208_bn1, and a third metal oxide layer 208_bw2 are stacked in this order. The first metal oxide layer 208_bw1 and the third metal oxide layer 208_bw2 are each a metal oxide layer whose conduction band minimum is at a high energy level. The second metal oxide layer 208_bn1 is a metal oxide layer whose conduction band minimum is at a lower energy level than that of the first metal oxide layer.

For the first metal oxide layer 208_bw1 and the third metal oxide layer 208_bw2, an M1 oxide (M1 is one kind or a plurality of kinds selected from Al, Ga, Si, Mg, Zr, Be, and B), an In-M1-Zn oxide, or an In-M1-M2-Zn oxide (M2 is one kind or a plurality of kinds selected from Ti, Ge, Sn, V, Ni, Mo, W, and Ta) is used. The first metal oxide layer 208_bw1 and the third metal oxide layer 208_bw2 preferably have an M1 content of 1 atomic % to 50 atomic %. The first metal oxide layer 208_bw1 and the third metal oxide layer 208_bw2 preferably have an M2 content of 0.01 atomic % to 5 atomic %. The first metal oxide layer 208_bw1 and the third metal oxide layer 208_bw2 have a carrier density of 1×10¹⁰ cm⁻³ or more and 1×10¹⁶ cm⁻³ or less, preferably approximately 1×10¹⁵ cm³. In this embodiment, the first metal oxide layer 208_bw1 and the third metal oxide layer 208_bw2 are formed using the same sputtering target.

In one example, the first metal oxide layer 208_bw1 contains an In—Ga—Ti—Zn oxide (In:Ga:Ti:Zn=5:0.5:0.5:7 [atomic ratio]), which is a wide bandgap material. In the In—Ga—Ti—Zn oxide, the valence of Ti is greater than those of In, Ga, and Zn.

Specifically, Zn has a valence of 2, In and Ga have a valence of 3, and Ti has a valence of 4. With the use of an element whose valence is greater than those of In, Ga, and Zn (here, Ti) in the metal oxide, this element serves as a carrier supply source and can increase the carrier density of the metal oxide. Furthermore, In, Ga, and Zn have an ionic bond, and Ti has a covalent bond. For this reason, in some cases where Ti is contained in the metal oxide, the generation of oxygen vacancies can be suppressed. Therefore, when the metal oxide of one embodiment of the present invention is used in a semiconductor layer of a transistor, the field-effect mobility of the transistor is improved and oxygen vacancies are reduced, whereby a semiconductor device with high reliability can be obtained.

Although Ti is described above in connection with the structure of the first metal oxide layer 208_bw1, Ti may be replaced with Ge, Sn, V, Ni, Mo, W, or Ta. For example, an In—Ga—Ge—Zn oxide layer may be formed using a metal oxide target having an atomic ratio of In:Ga:Ge:Zn=4:1:1:4, In:Ga:Ge:Zn=5:0.5:0.5:7, or a neighborhood thereof.

In one example, the second metal oxide layer 208_bn1 contains an In oxide, an In—Zn oxide, an In-M2 oxide (M2 is one kind or a plurality of kinds selected from Ti, Ge, Sn, V, Ni, Mo, W, and Ta), or an In-M2-Zn oxide, which is a narrow bandgap material. The second metal oxide layer 208_bn1 preferably has an M2 content of 0.01 atomic % to 5 atomic %. In particular, the In—Ti—Zn oxide may have a narrower bandgap than the In oxide and the In—Zn oxide in some cases. Thus, the In—Ti—Zn oxide can have a higher carrier density than the In oxide or the In—Zn oxide. Note that the carrier density of the second metal oxide layer 208_bn1, which is described as a narrow bandgap material, is preferably higher than or equal to 1×10¹⁸ cm⁻³ and lower than 1×10²¹ cm⁻³.

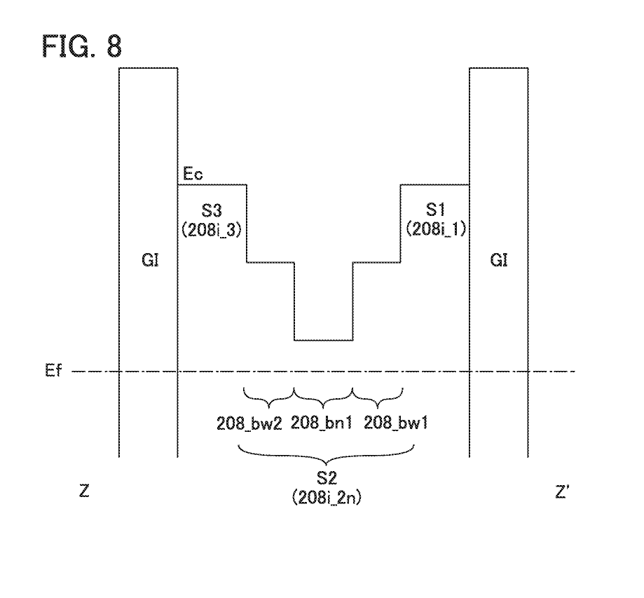

FIG. 8 is an example of a band diagram of the stacked-layer structure of the oxide along Z-Z′ section in FIG. 4B.

As illustrated in the region P7 in FIG. 4D, a side surface of the region 208i_2n is in contact with a side surface of the region 208n; thus, contact resistance can be lowered. In addition, the region 208i_2n of the metal oxide 208 includes the second metal oxide layer 208_bn1, i.e., a highly conductive region is in contact with the region 208n, that is, a source region; thus, contact resistance can be further lowered. Although not illustrated, a connection between the other side surface of the region 208i_2n and a side surface of the region 208n is similar to that in the region P7.

Since the metal oxide of one embodiment of the present invention includes the second metal oxide layer 208_bn1, contact resistance with the source region or the drain region is lowered. Therefore, the field-effect mobility of the transistor including the metal oxide can be increased.

The regions 208n are also in contact with the insulating film 216. The insulating film 216 contains nitrogen or hydrogen. Thus, nitrogen or hydrogen in the insulating film 216 is added to the regions 208n. The regions 208n have an increased carrier density owing to the addition of nitrogen or hydrogen from the insulating film 216.

The transistor 200C may further include an insulating film 218 over the insulating film 216, a conductive film 220a electrically connected to the region 208n through an opening 241a provided in the insulating films 216 and 218, and a conductive film 220b electrically connected to the region 208n through an opening 241b provided in the insulating films 216 and 218.

As illustrated in FIG. 4C, an opening 243 is provided in the insulating films 204 and 210. The conductive film 206 is electrically connected to the conductive film 212 through the opening 243. Thus, the same potential is applied to the conductive film 206 and the conductive film 212. Different potentials may be applied to the conductive film 206 and the conductive film 212 without providing the opening 243.

Note that the conductive film 206 functions as a first gate electrode (also referred to as a bottom-gate electrode), the conductive film 212 functions as a second gate electrode (also referred to as a top-gate electrode), the insulating film 204 functions as a first gate insulating film, and the insulating film 210 functions as a second gate insulating film.

In this manner, the transistor 200C in FIGS. 4A to 4C has a structure in which conductive films functioning as gate electrodes are provided over and under the metal oxide 208. As in the transistor 200C, a semiconductor device of one embodiment of the present invention may have two or more gate electrodes.

As illustrated in FIG. 4C, the metal oxide 208 faces the conductive film 206 functioning as a first gate electrode and the conductive film 212 functioning as a second gate electrode and is positioned between the two conductive films functioning as the gate electrodes.

Furthermore, the length of the conductive film 212 in the channel width direction is larger than the length of the metal oxide 208 in the channel width direction. In the channel width direction, the whole metal oxide 208 is covered with the conductive film 212 with the insulating film 210 provided therebetween. Since the conductive film 212 is connected to the conductive film 206 through the opening 243 provided in the insulating films 204 and 210, a side surface of the metal oxide 208 in the channel width direction faces the conductive film 212 with the insulating film 210 provided therebetween.

In other words, in the channel width direction of the transistor 200C, the conductive films 206 and 212 are connected to each other through the opening 243 provided in the insulating films 204 and 210, and the conductive films 206 and 212 surround the metal oxide 208 with the insulating films 204 and 210 positioned therebetween. That is, the transistor 200C has the s-channel structure described above.

Components of the semiconductor device of this embodiment will be described below in detail.

### [Substrate]

There is no particular limitation on a material and the like of the substrate 202 as long as the material has heat resistance high enough to withstand at least heat treatment to be performed later. For example, a glass substrate, a ceramic substrate, a quartz substrate, a sapphire substrate, or the like may be used as the substrate 202. Alternatively, a single crystal semiconductor substrate or a polycrystalline semiconductor substrate made of silicon or silicon carbide, a compound semiconductor substrate made of silicon germanium or the like, an SOI substrate, or the like may be used as the substrate 202. Further alternatively, any of these substrates provided with a semiconductor element may be used as the substrate 202. In the case where a glass substrate is used as the substrate 202, a large-area glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Alternatively, a flexible substrate may be used as the substrate 202, and the transistor may be provided directly on the flexible substrate. Further alternatively, a separation layer may be provided between the substrate 202 and the transistor. The separation layer can be used when part or the whole of a semiconductor device formed over the separation layer is completed and is then separated from the substrate 202 and transferred to another substrate. In such a case, the transistor can be transferred to a substrate having low heat resistance or a flexible substrate as well.

### [Conductive Film]

The conductive film 206 functioning as a first gate electrode, the conductive film 220a functioning as a source electrode, the conductive film 220b functioning as a drain electrode, and the conductive film 212 functioning as a second gate electrode can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these metal elements; or the like.

Furthermore, the conductive films 206, 220a, 220b, and 212 can be formed using an oxide conductor such as an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium, gallium, and zinc.

In particular, the above-described oxide conductor can be favorably used for the conductive film 212. Note that in this specification and the like, the oxide conductor may be referred to as OC. For example, the oxide conductor is obtained in the following manner. Oxygen vacancies are formed in an oxide semiconductor, and then hydrogen is added to the oxygen vacancies, so that a donor level is formed in the vicinity of the conduction band. As a result, the conductivity of the oxide semiconductor is increased, so that the oxide semiconductor becomes a conductor. An oxide semiconductor having become a conductor can be referred to as an oxide conductor. Oxide semiconductors generally have a visible light transmitting property because of their large energy gap. An oxide conductor is an oxide semiconductor having a donor level in the vicinity of the conduction band. Therefore, the influence of absorption due to the donor level on an oxide conductor is small, and the oxide conductor has a visible light transmitting property comparable to that of an oxide semiconductor.

A Cu-X alloy film (X is Mn, Ni, Cr, Fe, Co, Mo, Ta, or Ti) may be used for the conductive films 206, 220a, 220b, and 212. Use of a Cu-X alloy film enables the manufacturing cost to be reduced because wet etching process can be used in the processing.

In particular, the above-described Cu-X alloy film can be favorably used as the conductive films 220a and 220b. Specifically, the Cu-X alloy film is preferably a Cu—Mn alloy film.

### [Insulating Film Functioning as First Gate Insulating Film]

As the insulating film 204 functioning as a first gate insulating film of the transistor, an insulating layer including at least one of the following films formed by a plasma-enhanced chemical vapor deposition (PECVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that an insulating film of a single layer formed using a material selected from the above or an insulating film of two or more layers may be used as the insulating film 204.

Note that the insulating film that is in contact with the metal oxide 208 functioning as a channel region of the transistor is preferably an oxide insulating film and preferably includes a region including oxygen in excess of the stoichiometric composition (oxygen-excess region).

Note that one embodiment of the present invention is not limited to the above structure, and a nitride insulating film may be used as the insulating film that is in contact with the metal oxide 208. In one example, a silicon nitride film is formed and a surface of the silicon nitride film is oxidized by performing oxygen plasma treatment or the like on the surface of the silicon nitride film. In the case where oxygen plasma treatment or the like is performed on the surface of the silicon nitride film, the surface of the silicon nitride film may be oxidized at the atomic level. For this reason, oxygen might be undetectable by cross-sectional observation or the like of the transistor. That is, in the case of performing cross-sectional observation of the transistor, the silicon nitride film and the metal oxide may be observed to be in contact with each other in some cases.

Note that the silicon nitride film has a higher dielectric constant than a silicon oxide film and needs a larger thickness for capacitance equivalent to that of the silicon oxide film. Thus, when the silicon nitride film is included as the gate insulating film of the transistor, the thickness of the insulating film can be increased. This makes it possible to reduce a decrease in withstand voltage of the transistor and furthermore to increase the withstand voltage, thereby reducing electrostatic discharge damage to the transistor.

In the case where hafnium oxide is used as the insulating film 204, the following effect is attained. Hafnium oxide has a higher dielectric constant than silicon oxide and silicon oxynitride. Therefore, by using hafnium oxide, the thickness of the insulating film 204 can be made large as compared with the case where silicon oxide is used; thus, leakage current due to tunnel current can be low. That is, it is possible to provide a transistor with a low off-state current. Moreover, hafnium oxide with a crystalline structure has a higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited thereto.

### [Metal Oxide]

As the metal oxide 208, the multilayer structure of the metal oxide layers of one embodiment of the present invention can be used.

In order to obtain required semiconductor characteristics of a transistor, it is preferable that the carrier density, the impurity concentration, the defect density, the atomic ratio of a metal element to oxygen, the density, and the like of each of the metal oxide layers of the multilayer structure of the metal oxide (specifically, the first metal oxide layer 208_bw1, the second metal oxide layer 208_bn1, and the third metal oxide layer 208_bw2) be set to be appropriate.

### [Insulating Film Functioning as Second Gate Insulating Film]

The insulating film 210 functions as a second gate insulating film of the transistor. In addition, the insulating film 210 has a function of supplying oxygen to the metal oxide 208. That is, the insulating film 210 contains oxygen.

The insulating film 218 is preferably formed using an oxide insulating film whose oxygen content is higher than that in the stoichiometric composition. Part of oxygen is released by heating from the oxide insulating film whose oxygen content is higher than that in the stoichiometric composition. The oxide insulating film whose oxygen content is higher than that in the stoichiometric composition is an oxide insulating film of which the amount of released oxygen converted into oxygen atoms is greater than or equal to 1.0×10¹⁹ atoms/cm³, preferably greater than or equal to 3.0×10²⁰ atoms/cm³ in thermal desorption spectroscopy (TDS). Note that the surface temperature of the film in the TDS is preferably higher than or equal to 100° C. and lower than or equal to 700° C., or higher than or equal to 100° C. and lower than or equal to 500° C.

A silicon oxide film, a silicon oxynitride film, or the like with a thickness greater than or equal to 30 nm and less than or equal to 500 nm, preferably greater than or equal to 50 nm and less than or equal to 400 nm can be used as the insulating film 218.

It is preferable that the amount of defects in the insulating film 218 be small; as a typical example, the spin density corresponding to a signal which appears at g=2.001 due to a dangling bond of silicon be lower than 1.5×10¹⁸ spins/cm³, further preferably lower than or equal to 1×10¹⁸ spins/cm³ by ESR measurement.

### [Insulating Film Functioning as Protective Insulating Film]

The insulating film 216 functions as a protective insulating film for the transistor.

The insulating film 216 contains either hydrogen or nitrogen, or both. Alternatively, the insulating film 216 contains nitrogen and silicon. The insulating film 216 has a function of blocking oxygen, hydrogen, water, alkali metal, alkaline earth metal, or the like. It is possible to prevent outward diffusion of oxygen from the metal oxide 208, outward diffusion of oxygen included in the insulating film 210, and entry of hydrogen, water, or the like into the metal oxide 208 from the outside by providing the insulating film 216.

As the insulating film 216, a nitride insulating film can be used, for example. The nitride insulating film is formed using silicon nitride, silicon nitride oxide, aluminum nitride, aluminum nitride oxide, or the like.

Although the above-described variety of films such as the conductive films, the insulating films, the metal oxide, and the metal film can be formed by a sputtering method or a PECVD method, they may be formed by another method, e.g., a thermal chemical vapor deposition (CVD) method. Examples of the thermal CVD method include a metal organic chemical vapor deposition (MOCVD) method, an atomic layer deposition (ALD) method, and the like.

The thermal CVD method has an advantage that no defect due to plasma damage is generated since it does not utilize plasma for forming a film.

Deposition by the thermal CVD method may be performed in such a manner that a source gas and an oxidizer are supplied to a chamber at a time while the pressure in the chamber is set to an atmospheric pressure or a reduced pressure, and the source gas and the oxidizer react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated.

The variety of films such as the conductive films, the insulating films, and the metal oxide in this embodiment can be formed by a thermal CVD method such as an MOCVD method or an ALD method.

### <Method for Manufacturing Semiconductor Device>

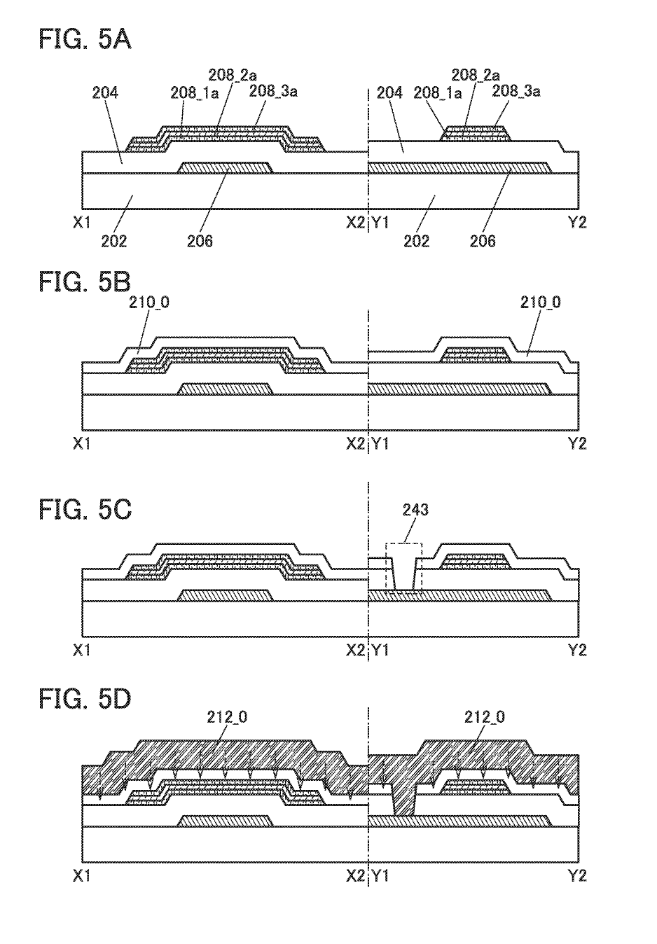

Next, a method for manufacturing the transistor 200C that is a semiconductor device of one embodiment of the present invention is described with reference to FIGS. 5A to 5D, FIGS. 6A to 6C, and FIGS. 7A to 7C.

FIGS. 5A to 5D, FIGS. 6A to 6C, and FIGS. 7A to 7C are cross-sectional views illustrating a method for manufacturing a semiconductor device. In FIGS. 5A to 5D, FIGS. 6A to 6C, and FIGS. 7A to 7C, cross-sectional views in the channel length direction are on the left side, and cross-sectional views in the channel width direction are on the right side.

First, the conductive film 206 is formed over the substrate 202. Next, the insulating film 204 is formed over the substrate 202 and the conductive film 206, and a first metal oxide layer, a second metal oxide layer, and a third metal oxide layer are formed over the insulating film 204. Then, the first metal oxide layer, the second metal oxide layer, and the third metal oxide layer are processed into an island shape, whereby a metal oxide layer 208_1a, a metal oxide layer 208_2a, and a metal oxide layer 208_3a are formed (see FIG. 5A). Although the metal oxide layer 208_2a is illustrated as one layer in FIG. 5A for simplicity, the metal oxide layer 208_2a has a three-layer structure and corresponds to the three layers 208_bw1, 208_bn1, and 208_bw2, illustrated in FIG. 4D.

The conductive film 206 can be formed using a material selected from the above-mentioned materials. In this embodiment, for the conductive film 206, a stack including a 50-nm-thick tungsten film and a 400-nm-thick copper film is formed with a sputtering apparatus.

To process a conductive film to be the conductive film 206, a wet etching method and/or a dry etching method can be used. In this embodiment, in the processing of the conductive film into the conductive film 206, the copper film is etched by a wet etching method, and then the tungsten film is etched by a dry etching method.

The insulating film 204 can be formed by a sputtering method, a CVD method, an evaporation method, a pulsed laser deposition (PLD) method, a printing method, a coating method, or the like as appropriate. In this embodiment, as the insulating film 204, a 400-nm-thick silicon nitride film and a 50-nm-thick silicon oxynitride film are formed with a PECVD apparatus.

After the insulating film 204 is formed, oxygen may be added to the insulating film 204. As oxygen added to the insulating film 204, an oxygen radical, an oxygen atom, an oxygen atomic ion, an oxygen molecular ion, or the like may be used. Oxygen can be added by an ion doping method, an ion implantation method, a plasma treatment method, or the like. Alternatively, a film that suppresses oxygen release may be formed over the insulating film 204, and then oxygen may be added to the insulating film 204 through the film.

The film that suppresses oxygen release can be formed using a conductive film or a semiconductor film containing one or more of indium, zinc, gallium, tin, aluminum, chromium, tantalum, titanium, molybdenum, nickel, iron, cobalt, and tungsten.

In the case where oxygen is added by plasma treatment in which oxygen is excited by a microwave to generate high-density oxygen plasma, the amount of oxygen added to the insulating film 204 can be increased.

The metal oxide layer 208_1a, the metal oxide layer 208_2a, and the metal oxide layer 208_3a are preferably formed successively in a vacuum using a sputtering apparatus. By successive formation of the metal oxide layer 208_1a, the metal oxide layer 208_2a, and the metal oxide layer 208_3a in a vacuum using a sputtering apparatus, impurities (such as hydrogen and water) that can be attached to each interface can be reduced.

The metal oxide layer 208_2a is preferably formed with a lower oxygen partial pressure than the metal oxide layer 208_1a and/or the metal oxide layer 208_3a. In forming the metal oxide layer 208_1a, the metal oxide layer 208_2a, and the metal oxide layer 208_3a, an inert gas (such as a helium gas, an argon gas, or a xenon gas) may be mixed in addition to the oxygen gas. Note that the proportion of the oxygen gas in the whole deposition gas (hereinafter also referred to as oxygen flow ratio) in forming the metal oxide layer 208_1a is more than or equal to 70% and less than or equal to 100%, preferably more than or equal to 80% and less than or equal to 100%, further preferably more than or equal to 90% and less than or equal to 100%. The oxygen flow ratio in forming the metal oxide layer 208_2a is more than 0% and less than or equal to 30%, preferably more than or equal to 5% and less than or equal to 15%. The oxygen flow ratio in forming the metal oxide layer 208_3a is more than or equal to 70% and less than or equal to 100%, preferably more than or equal to 80% and less than or equal to 100%, further preferably more than or equal to 90% and less than or equal to 100%.

Note that the metal oxide layer 208_2a may be formed at a lower substrate temperature than the metal oxide layer 208_1a and/or the metal oxide layer 208_3a.

The thickness of the metal oxide layer 208_1a is more than or equal to 1 nm and less than 20 nm, preferably more than or equal to 5 nm and less than or equal to 10 nm. The thickness of the metal oxide layer 208_3a is more than or equal to 1 nm and less than 20 nm, preferably more than or equal to 5 nm and less than or equal to 15 nm.

The metal oxide layer 208_2a has a three-layer structure. The thickness of each of the three layers is more than or equal to 0.1 nm and less than 30 nm, preferably more than or equal to 0.1 nm and less than or equal to 10 nm, further preferably more than or equal to 0.1 nm and less than or equal to 3 nm.

Note that the metal oxide 208 is formed while being heated, so that the crystallinity of the metal oxide 208 can be increased. The crystal structure of the metal oxide 208 is not particularly limited as long as the metal oxide 208 is an oxide semiconductor having a non-single-crystal structure. On the other hand, in the case where a large-sized glass substrate (e.g., the 6th generation to the 10th generation) is used as the substrate 202 and the metal oxide 208 is formed at a substrate temperature higher than or equal to 200° C. and lower than or equal to 300° C., the substrate 202 might be changed in shape (distorted or warped). In the case where a large-sized glass substrate is used, the change in the shape of the glass substrate can be suppressed by forming the metal oxide 208 at a substrate temperature higher than or equal to 100° C. and lower than 200° C.

In addition, increasing the purity of the sputtering gas is necessary. For example, when a gas which is highly purified to have a dew point of −40° C. or lower, preferably −80° C. or lower, further preferably −100° C. or lower, still further preferably −120° C. or lower, is used as the sputtering gas, i.e., the oxygen gas or the argon gas, entry of moisture or the like into the metal oxide can be minimized.

In the case where the metal oxide is deposited by a sputtering method, a chamber in a sputtering apparatus is preferably evacuated to be a high vacuum state (to the degree of about 5×10⁻⁷ Pa to 1×10⁻⁴ Pa) with an adsorption vacuum evacuation pump such as a cryopump in order to remove water or the like, which serves as an impurity for the metal oxide, as much as possible. In particular, the partial pressure of gas molecules corresponding to H₂O (gas molecules corresponding to m/z=18) in the chamber in the standby mode of the sputtering apparatus is preferably lower than or equal to 1×10⁻⁴ Pa, further preferably lower than or equal to 5×10⁻⁵ Pa.

To process the first metal oxide layer, the second metal oxide layer, and the third metal oxide layer into the metal oxide layer 208_1a, the metal oxide layer 208_2a, and the metal oxide layer 208_3a, a wet etching method and/or a dry etching method can be used.

After the metal oxide layer 208_1a, the metal oxide layer 208_2a, and the metal oxide layer 208_3a are formed, the metal oxide layer 208_1a, the metal oxide layer 208_2a, and the metal oxide layer 208_3a may be dehydrated or dehydrogenated by heat treatment. The temperature of the heat treatment is typically higher than or equal to 150° C. and lower than the strain point of the substrate, higher than or equal to 250° C. and lower than or equal to 450° C., or higher than or equal to 300° C. and lower than or equal to 450° C.

The heat treatment can be performed in an inert gas atmosphere containing nitrogen or a rare gas such as helium, neon, argon, xenon, or krypton. Alternatively, the heat treatment may be performed in an inert gas atmosphere first, and then in an oxygen atmosphere. It is preferable that the above inert gas atmosphere and the above oxygen atmosphere not contain hydrogen, water, and the like. The treatment time may be longer than or equal to 3 minutes and shorter than or equal to 24 hours.

An electric furnace, an RTA apparatus, or the like can be used for the heat treatment. With the use of an RTA apparatus, the heat treatment can be performed at a temperature higher than or equal to the strain point of the substrate if the heating time is short. Therefore, the heat treatment time can be shortened.

By depositing the metal oxide while it is heated or by performing heat treatment after the deposition of the metal oxide, the hydrogen concentration in the metal oxide, which is measured by SIMS, can be 5×10¹⁹ atoms/cm³ or lower, 1×10¹⁹ atoms/cm³ or lower, 5×10¹⁸ atoms/cm³ or lower, 1×10¹⁸ atoms/cm³ or lower, 5×10¹⁷ atoms/cm³ or lower, or 1×10¹⁶ atoms/cm³ or lower.

Next, an insulating film 210_0 is formed over the insulating film 204 and the metal oxide 208 (see FIG. 5B).

For the insulating film 210_0, a silicon oxide film, a silicon oxynitride film, or a silicon nitride film can be formed with a plasma-enhanced chemical vapor deposition apparatus (also referred to as a PECVD apparatus or simply a plasma CVD apparatus). In this case, a deposition gas containing silicon and an oxidizing gas are preferably used as a source gas. Typical examples of the deposition gas containing silicon include silane, disilane, trisilane, and silane fluoride. As examples of the oxidizing gas, oxygen, ozone, dinitrogen monoxide, and nitrogen dioxide can be given.

A silicon oxynitride film having few defects can be formed as the insulating film 210_0 with the PECVD apparatus under the conditions that the flow rate of the oxidizing gas is more than 20 times and less than 100 times or is more than or equal to 40 times and less than or equal to 80 times the flow rate of the deposition gas and that the pressure in a treatment chamber is lower than 100 Pa or lower than or equal to 50 Pa.

As the insulating film 210_0, a dense silicon oxide film or a dense silicon oxynitride film can be formed under the following conditions: the substrate placed in a vacuum-evacuated treatment chamber of the PECVD apparatus is held at a temperature higher than or equal to 280° C. and lower than or equal to 400° C.; the pressure in the treatment chamber into which a source gas is introduced is set to be higher than or equal to 20 Pa and lower than or equal to 250 Pa, preferably higher than or equal to 100 Pa and lower than or equal to 250 Pa; and a high-frequency power is supplied to an electrode provided in the treatment chamber.

The insulating film 210_0 may be formed by a PECVD method using a microwave. A microwave refers to a wave in the frequency range of 300 MHz to 300 GHz. In the case of using a microwave, electron temperature and electron energy are low. Furthermore, in supplied power, the proportion of power used for acceleration of electrons is low, and therefore, much more power can be used for dissociation and ionization of molecules. Thus, plasma with a high density (high-density plasma) can be excited. This method causes little plasma damage to the deposition surface or a deposit, so that the insulating film 210_0 having few defects can be formed.

In this embodiment, as the insulating film 210_0, a 100-nm-thick silicon oxynitride film is formed with the PECVD apparatus.

Subsequently, a mask is formed by lithography in a desired position over the insulating film 210_0, and then the insulating film 210_0 and the insulating film 204 are partly etched, so that the opening 243 reaching the conductive film 206 is formed (see FIG. 5C).

To form the opening 243, a wet etching method and/or a dry etching method can be used. In this embodiment, the opening 243 is formed by a dry etching method.

Next, a conductive film 212_0 is formed over the conductive film 206 and the insulating film 210_0 so as to cover the opening 243. In the case where a metal oxide film is used as the conductive film 212_0, for example, oxygen might be added to the insulating film 210_0 during the formation of the conductive film 212_0 (see FIG. 5D).

In FIG. 5D, oxygen added to the insulating film 210_0 is schematically shown by arrows. Furthermore, the conductive film 212_0 formed to cover the opening 243 is electrically connected to the conductive film 206.

In the case where a metal oxide film is used as the conductive film 212_0, the conductive film 212_0 is preferably formed by a sputtering method in an atmosphere containing an oxygen gas. Formation of the conductive film 212_0 in an atmosphere containing an oxygen gas allows suitable addition of oxygen to the insulating film 210_0. Note that a method for forming the conductive film 212_0 is not limited to a sputtering method, and another method such as an ALD method may be used.

In this embodiment, a 100-nm-thick In—Ga—Zn oxide (In:Ga:Zn=4:2:4.1 (atomic ratio)) is formed as the conductive film 212_0 by a sputtering method. Oxygen addition treatment may be performed on the insulating film 210_0 before or after the formation of the conductive film 212_0. The oxygen addition treatment can be performed similarly to the oxygen addition treatment that can be performed after the formation of the insulating film 204.

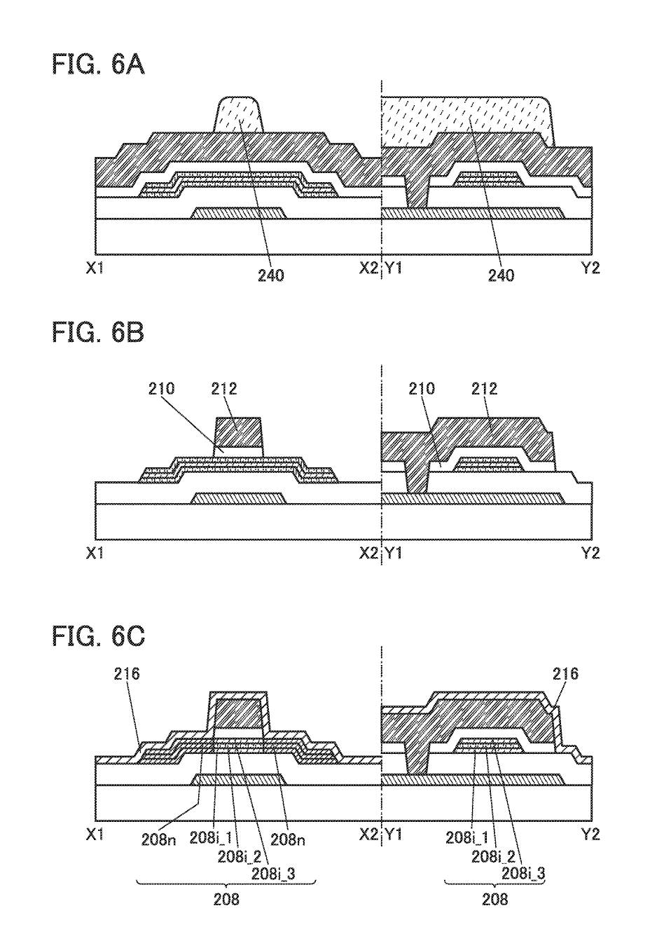

Subsequently, a mask 240 is formed by a lithography process in a desired position over the conductive film 212_0 (see FIG. 6A).

Next, etching is performed from above the mask 240 to process the conductive film 212_0 and the insulating film 210_0. After the processing of the conductive film 212_0 and the insulating film 210_0, the mask 240 is removed. As a result of the processing of the conductive film 212_0 and the insulating film 210_0, the island-shaped conductive film 212 and the island-shaped insulating film 210 are formed (see FIG. 6B).

In this embodiment, the conductive film 212_0 and the insulating film 210_0 are processed by a dry etching method.

In the processing of the conductive film 212_0 and the insulating film 210_0, the thickness of the metal oxide 208 in a region not overlapping with the conductive film 212 is decreased in some cases. In other cases, in the processing of the conductive film 212_0 and the insulating film 210_0, the thickness of the insulating film 204 in a region not overlapping with the metal oxide 208 is decreased. In the processing of the conductive film 212_0 and the insulating film 210_0, an etchant or an etching gas (e.g., chlorine) might be added to the metal oxide 208 or the constituent element of the conductive film 212_0 or the insulating film 210_0 might be added to the metal oxide 208.

Next, the insulating film 216 is formed over the insulating film 204, the metal oxide 208, and the conductive film 212. By the formation of the insulating film 216, the metal oxide 208 in contact with the insulating film 216 becomes the regions 208n. In addition, the region 2080, the region 208i_2, and the region 208i_3 are formed in the metal oxide 208 overlapping with the conductive film 212 (see FIG. 6C).

The insulating film 216 can be formed using a material selected from the above-mentioned materials. In this embodiment, as the insulating film 216, a 100-nm-thick silicon nitride oxide film is formed with a PECVD apparatus. In the formation of the silicon nitride oxide film, two steps, i.e., plasma treatment and deposition treatment, are performed at a temperature of 220° C. The plasma treatment is performed under the following conditions: an argon gas at a flow rate of 100 sccm and a nitrogen gas at a flow rate of 1000 sccm are introduced into a chamber before deposition; the pressure in the chamber is set to 40 Pa; and a power of 1000 W is supplied to an RF power source (27.12 MHz). The deposition treatment is performed under the following conditions: a silane gas at a flow rate of 50 sccm, a nitrogen gas at a flow rate of 5000 sccm, and an ammonia gas at a flow rate of 100 sccm are introduced into the chamber; the pressure in the chamber is set to 100 Pa; and a power of 1000 W is supplied to the RF power source (27.12 MHz).

When a silicon nitride oxide film is used as the insulating film 216, nitrogen or hydrogen in the silicon nitride oxide film can be supplied to the regions 208n in contact with the insulating film 216. In addition, when the formation temperature of the insulating film 216 is the above temperature, release of excess oxygen contained in the insulating film 210 to the outside can be suppressed.

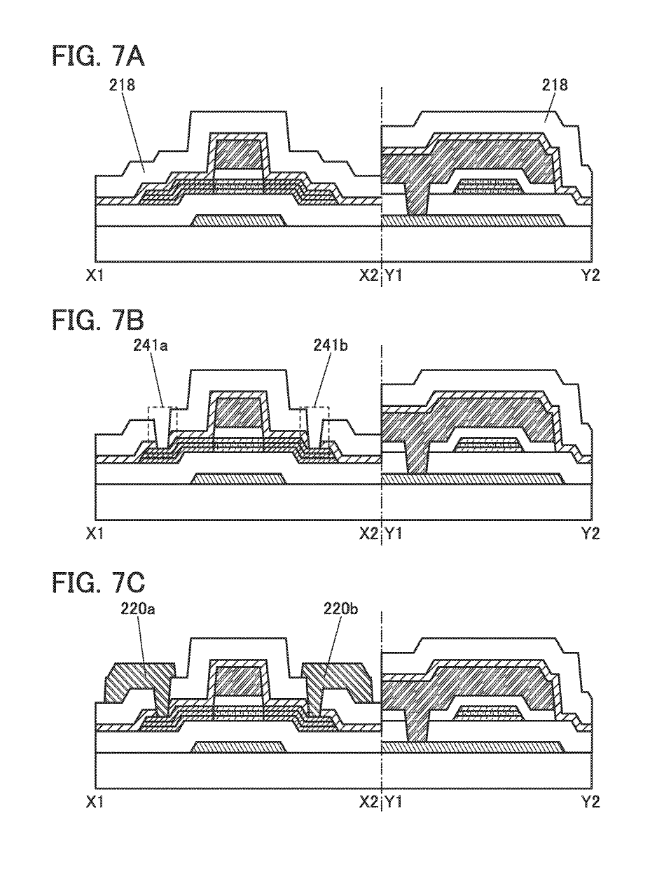

Next, the insulating film 218 is formed over the insulating film 216 (see FIG. 7A).

The insulating film 218 can be formed using a material selected from the above-mentioned materials. In this embodiment, as the insulating film 218, a 300-nm-thick silicon oxynitride film is formed with a PECVD apparatus.

Subsequently, a mask is formed by lithography in a desired position over the insulating film 218, and then the insulating film 218 and the insulating film 216 are partly etched, so that the opening 241a and the opening 241b reaching the regions 208n are formed (see FIG. 7B).

To etch the insulating film 218 and the insulating film 216, a wet etching method and/or a dry etching method can be used. In this embodiment, the insulating film 218 and the insulating film 216 are processed by a dry etching method.

Next, a conductive film is formed over the regions 208n and the insulating film 218 so as to cover the openings 241a and 241b and the conductive film is processed into a desired shape, whereby the conductive films 220a and 220b are formed (see FIG. 7C).

The conductive films 220a and 220b can be formed using a material selected from the above-mentioned materials. In this embodiment, for the conductive films 220a and 220b, a stack including a 50-nm-thick tungsten film and a 400-nm-thick copper film is formed with a sputtering apparatus.

To process the conductive film to be the conductive films 220a and 220b, a wet etching method and/or a dry etching method can be used. In this embodiment, in the processing of the conductive film into the conductive films 220a and 220b, the copper film is etched by a wet etching method, and then the tungsten film is etched by a dry etching method.

Through the above steps, the transistor 200C in FIGS. 4A to 4C can be manufactured.

Note that the structures and the methods described in this embodiment can be combined as appropriate with any of the structures and the methods described in the other embodiments.

### Embodiment 2

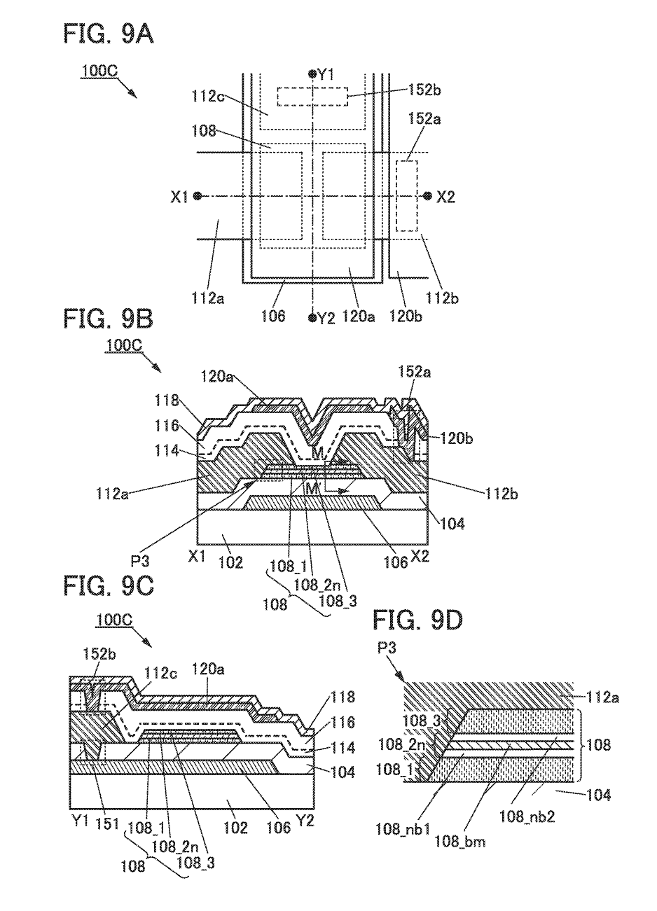

In this embodiment, a modification example of the transistor 200C described in Embodiment 1 will be described with reference to FIGS. 9A to 9D.

FIGS. 9A to 9C are a top view and cross-sectional views of a transistor 100C. FIG. 9D is an enlarged cross-sectional view of a region P3 in FIG. 9B.

The transistor 100C illustrated in FIGS. 9A to 9C includes a metal oxide 108_1, a metal oxide 108_2n over the metal oxide 108_1, and a metal oxide 108_3 over the metal oxide 108_2n.

For example, a first metal oxide layer whose conduction band minimum is at a high energy level is used as the metal oxide 108_1 of the metal oxide 108. A second metal oxide layer whose conduction band minimum is at a lower energy level than that of the first metal oxide layer is used as a first layer of the metal oxide 108_2n. A third metal oxide layer whose conduction band minimum is at an energy level higher than that of the second metal oxide layer and lower than that of the first metal oxide layer is used as a second layer of the metal oxide 108_2n. A fourth metal oxide layer whose conduction band minimum is at a lower energy level than that of the third metal oxide layer is used as a third layer of the metal oxide 108_2n. A fifth metal oxide layer whose conduction band minimum is at a high energy level is used as the metal oxide 108_3.

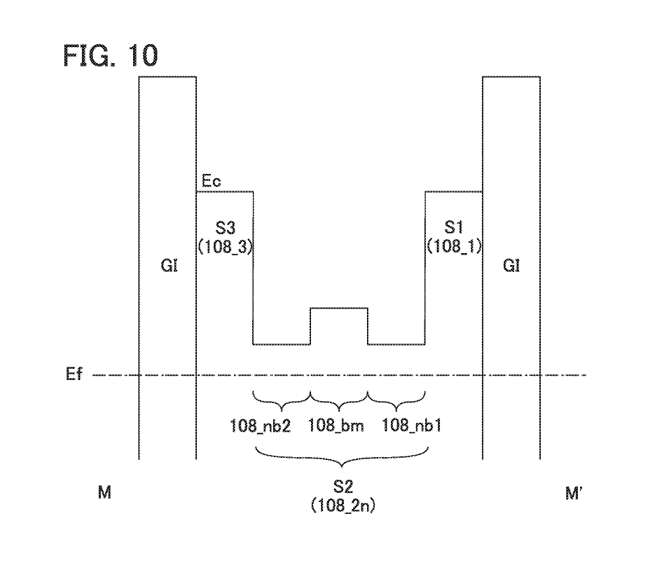

FIG. 10 is an example of a band diagram of the above-described stacked-layer structure of the oxide along M-M′ section in FIG. 9B.

Here, the band diagram illustrated in FIG. 8 and the band diagram illustrated in FIG. 10 are compared with each other. The conduction band minimum of a metal oxide layer corresponding to 208_bn1 illustrated in FIG. 8 is at the lowest energy level in S2. In contrast, the conduction band minimum of a metal oxide layer corresponding to 108_bm illustrated in FIG. 10 is not at the lowest energy level in S2. Specifically, in the case of the band diagram in FIG. 10, the energy level of the conduction band minimum of the metal oxide layer corresponding to 108_bm is positioned between the energy level of the conduction band minimum of S1 and S3 and the energy level of the conduction band minimum of metal oxide layers corresponding to 108_nb2 and 108_nb1.

For example, metal oxide layers of the multilayer structure whose band diagram is illustrated in FIG. 8 are formed by a method in which, after GI is formed, S1 is formed; the metal oxide layer corresponding to 208_bw1, which is a wide bandgap material, is formed; the metal oxide layer corresponding to 208_bn1, which is a narrow bandgap material, is formed; the metal oxide layer corresponding to 208_bw2, which is a wide bandgap material, is formed; and after S3 is formed, GI is formed. By this method, in some cases, excess oxygen cannot be supplied to the metal oxide layer corresponding to 208_bn1, which is a narrow bandgap material.

In contrast, when metal oxide layers of the multilayer structure whose band diagram is illustrated in FIG. 10 are formed, excess oxygen can be supplied, in some cases, to metal oxide layers in contact with 108_bm, here, the metal oxide layers corresponding to 108_nb2 and 108_nb1, by forming the metal oxide layer corresponding to 108_bm under conditions where the oxygen flow ratio is high (e.g., conditions where the flow ratio of oxygen in the whole deposition gas is more than or equal to 70% and less than 100%).

Therefore, the metal oxide layers of the multilayer structure whose band diagram is illustrated in FIG. 10 are preferable because both a metal oxide layer with high field-effect mobility and metal oxide layers with reduced oxygen vacancies and high reliability can be obtained in some cases.

Note that the structure and the method described in this embodiment can be combined as appropriate with any of the structures and the methods described in the other embodiments.

### Embodiment 3

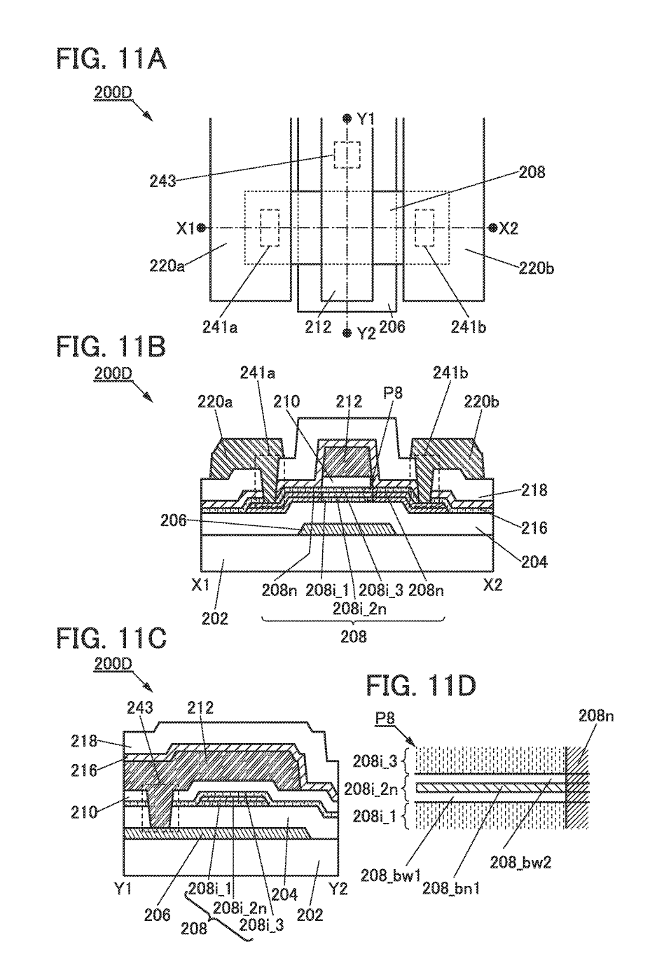

In this embodiment, a modification example of the transistor 200C described in Embodiment 1 will be described with reference to FIGS. 11A to 11D.

FIGS. 11A to 11C are a top view and cross-sectional views of a transistor 200D that is a modification example of the transistor 200C illustrated in FIGS. 4A to 4C. FIG. 11D is an enlarged cross-sectional view of a region P8 in FIG. 11B.

Note that the region P8 illustrated in FIG. 11D has a structure similar to that of the region P7 illustrated in FIG. 4D and is therefore not described here.

Note that the metal oxide 208 of the transistor 200D differs from the metal oxide 208 of the transistor 200C in the shape of the region 2080. Specifically, in the metal oxide 208 of the transistor 200D, side surfaces of the region 2080 and the region 208i_2n are covered with the region 208i_3. With such a shape, the side surfaces of the region 208i_1 and the region 208i_2n are not in contact with the insulating film 210. In such a structure, impurities that might enter the region 208i_1 and the region 208i_2n, particularly the region 208i_2n, can be reduced, whereby a semiconductor device with high reliability can be provided.

Note that the structure and the method described in this embodiment can be combined as appropriate with any of the structures and the methods described in the other embodiments.

### Embodiment 4

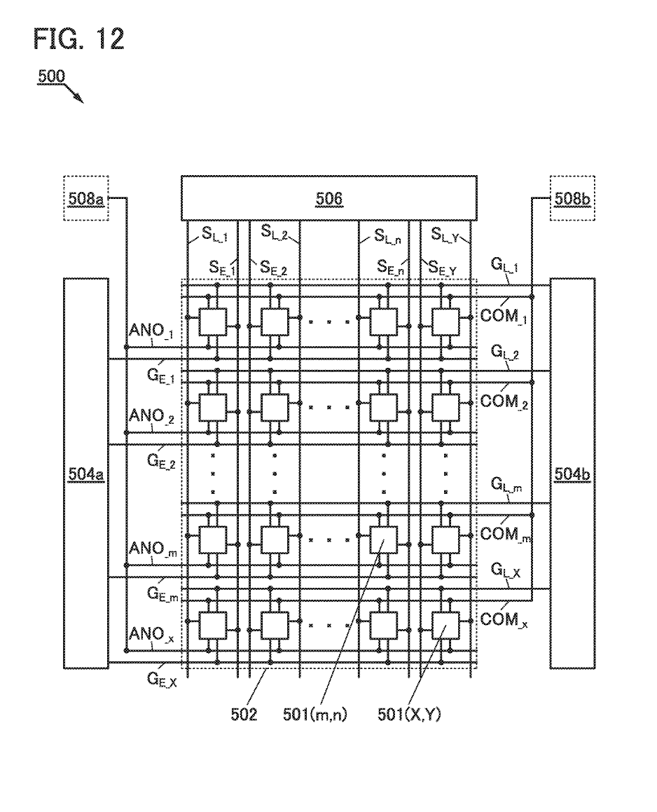

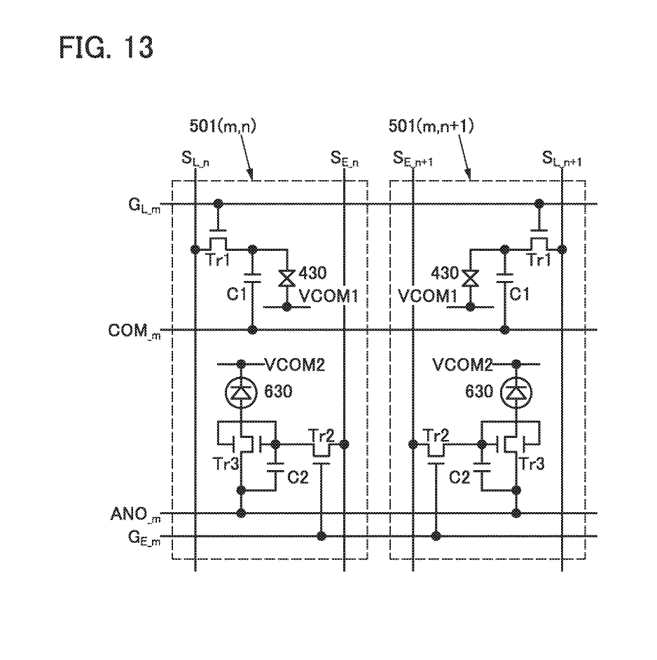

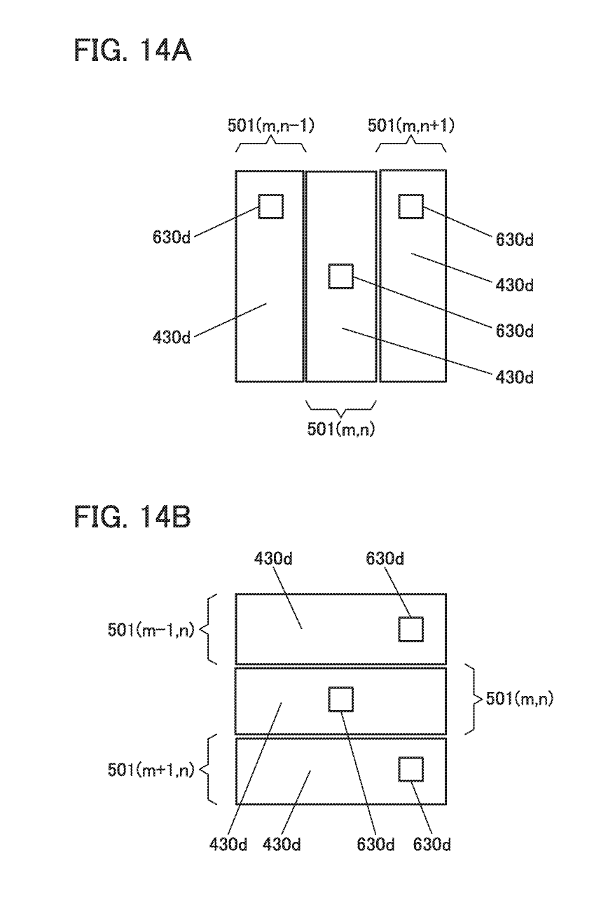

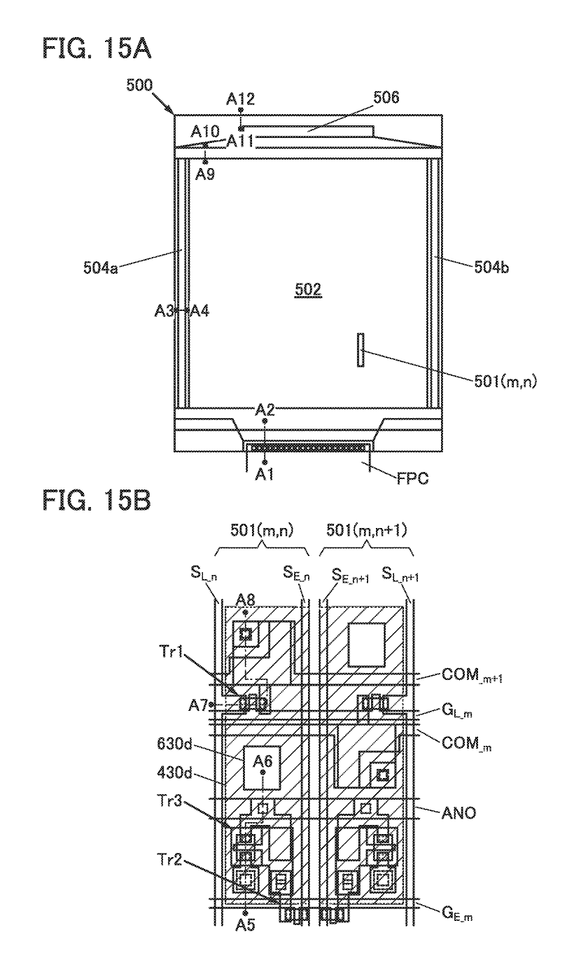

In this embodiment, a display device of one embodiment of the present invention which includes any of the transistors in Embodiment 1 will be described with reference to FIG. 12, FIG. 13, FIGS. 14A and 14B, and FIGS. 15A and 15B.

First, a configuration of a display device will be described with reference to FIG. 12. A display device 500 illustrated in FIG. 12 includes a pixel portion 502, and gate driver circuit portions 504a and 504b and a source driver circuit portion 506 which are placed outside the pixel portion 502.

The pixel portion 502 includes pixel circuits 501(1, 1) to 501(X, Y) arranged in X rows (X is a natural number of 2 or more) and Y columns (Y is a natural number of 2 or more). Each of the pixel circuits 501(1, 1) to 501(X, Y) includes two display elements having different functions. One of the two display elements has a function of reflecting incident light, and the other has a function of emitting light. Note that the details of the two display elements are described later.

Some or all of the gate driver circuit portions 504a and 504b and the source driver circuit portion 506 are preferably formed over a substrate over which the pixel portion 502 is formed. Thus, the number of components and the number of terminals can be reduced. In the case where some or all of the gate driver circuit portions 504a and 504b and the source driver circuit portion 506 are not formed over the substrate over which the pixel portion 502 is formed, a separately prepared driver circuit board (e.g., a driver circuit board formed using a single crystal semiconductor film or a polycrystalline semiconductor film) may be formed in the display device 500 by chip on glass (COG) or tape automated bonding (TAB).

The gate driver circuit portions 504a and 504b have a function of outputting a signal (a scan signal) for selecting the pixel circuits 501(1, 1) to 501(X, Y). The source driver circuit portion 506 has a function of supplying a signal (data signal) for driving the display elements included in the pixel circuits 501(1, 1) to 501(X, Y).

The gate driver circuit portion 504a has a function of controlling the potentials of wirings supplied with scan signals (hereinafter, such wirings are referred to as scan lines G_{E}_{_}₁ to G_{E}_{_}_{X}) or a function of supplying an initialization signal. The gate driver circuit portion 504b has a function of controlling the potentials of wirings supplied with scan signals (hereinafter, such wirings are referred to as scan lines G_{L}_{_}₁, to G_{L}_{_}_{X}) or a function of supplying an initialization signal. Without being limited thereto, the gate driver circuit portions 504a and 504b can each control or supply another signal.

Although the structure in which the two gate driver circuit portions 504a and 504b are provided as gate driver circuit portions is illustrated in FIG. 12, the number of gate driver circuit portions is not limited thereto, and one or three or more gate driver circuit portions may be provided.

The source driver circuit portion 506 has a function of generating a data signal to be written to the pixel circuits 501(1, 1) to 501(X, Y) on the basis of an image signal, a function of controlling the potentials of wirings supplied with data signals (such wirings are hereinafter referred to as signal lines S_{L}_{_}₁ to S_{L}_{_}_{Y} and signal lines S_{E}_{_}₁ to S_{E}_{_}_{Y}), or a function of supplying an initialization signal. Without being limited thereto, the source driver circuit portion 506 may have a function of generating, controlling, or supplying another signal.

The source driver circuit portion 506 includes a plurality of analog switches or the like. The source driver circuit portion 506 can output, as data signals, time-divided image signals obtained by sequentially turning on the plurality of analog switches.

Although the structure where one source driver circuit portion 506 is provided is illustrated in FIG. 12, the number of source driver circuit portions is not limited thereto, and a plurality of source driver circuit portions may be provided in the display device 500. For example, two source driver circuit portions may be provided so that the signal lines S_{L}_{_}₁ to S_{L}_{_}_{Y} are controlled by one of the source driver circuit portions and the signal lines S_{E}_{_}₁ to S_{E}_{_}_{Y} are controlled by the other of the source driver circuit portions.

A pulse signal is input to each of the pixel circuits 501(1, 1) to 501(X, Y) through one of the scan lines G_{L}_{_}₁ to G_{L}_{_}_{X} and the scan lines G_{E}_{_}₁ to G_{E}_{_}_{X}. A data signal is input to each of the pixel circuits 501(1, 1) to 501(X, Y) through one of the signal lines S_{L}_{_}₁ to S_{L}_{_}_{Y} and the signal lines S_{E}_{_}₁ to S_{E}_{_{—Y}}.

For example, the pixel circuit 501(m, n) in the m-th row and the n-th column (m is a natural number of X or less, and n is a natural number of Y or less) is supplied with pulse signals from the gate driver circuit portion 504a through the scan lines G_{L}_{_{—m}} and G_{E}_{_}ₘ and supplied with a data signal from the source driver circuit portion 506 through the signal lines S_{L}_{_}ₙ and S_{E}_{_}ₙ in accordance with the potentials of the scan lines G_{L}_{_}ₘ and G_{E}_{_}ₘ.

The pixel circuit 501(m, n) includes two display elements as described above. The scan lines G_{L}_{_}₁ to G_{L}_{_}_{X} are wirings which control the potential of a pulse signal supplied to one of the two display elements. The scan lines G_{E}_{_}₁ to G_{E}_{_}_{X} are wirings which control the potential of the other of the two display elements.

The signal lines S_{L}_{_}₁ to S_{L}_{_}_{Y} are wirings which control the potential of a data signal supplied to one of the two display elements. The signal lines S_{E}_{_}₁ to S_{E}_{_}_{Y} are wirings which control the potential of a data signal supplied to the other of the two display elements.

External circuits 508a and 508b are connected to the display device 500. Note that the external circuits 508a and 508b may be formed in the display device 500.

As shown in FIG. 12, the external circuit 508a is electrically connected to wirings supplied with anode potentials (hereinafter referred to as anode lines ANO ₁ to ANO ₓ) and the external circuit 508b is electrically connected to wirings supplied with a common potential (hereinafter referred to as common lines COM ₁ to COM _{X}).

Next, the configuration of the pixel circuit 501(m, n) is described with reference to FIG. 13.

FIG. 13 is a circuit diagram showing the pixel circuit 501(m, n) and an adjacent pixel circuit 501(m, n+1) in a column direction of the pixel circuit 501(m, n) which are included in the display device 500 of one embodiment of the present invention. In this specification and the like, the column direction is a direction in which the value of n of the signal line S_{L}_{_}ₙ (or the signal line S_{E}_{_}ₙ) increases or decreases and the row direction is a direction in which the value of m of the scan line G_{L}_{_}ₙ (or the scan line G_{E}_{_}ₘ) increases or decreases.

The pixel circuit 501(m, n) includes a transistor Tr1, a transistor Tr2, a transistor Tr3, a capacitor C1, a capacitor C2, a display element 430, and a display element 630. The pixel circuit 501(m, n+1) has a similar structure.

The pixel circuit 501(m, n) is electrically connected to the signal line S_{L}_{_}ₙ, the signal line S_{E}_{_}ₙ, the scan line G_{L}_{_}ₘ, the scan line G_{E}_{_}ₘ, a common line COM ₘ, a common line VCOM1, a common line VCOM2, and an anode line ANO ₘ. The pixel circuit 501(m, n+1) is electrically connected to a signal line S_{L}_{_}ₙ₊₁, a signal line S_{E}_{_}ₙ₊₁, the scan line G_{L}_{_}ₘ, the scan line G_{E}_{_}ₘ, the common line COM ₘ, the common line VCOM1, the common line VCOM2, and the anode line ANO ₘ.

Each of the signal lines S_{L}_{_}ₙ and S_{L}_{_}ₙ₊₁, the scan line G_{L}_{_}ₘ, the common line COM ₘ, and the common line VCOM1 is a wiring for driving the display element 430. Each of the signal lines S_{E}_{_}ₙ and S_{E}_{_}ₙ₊₁, the scan line G_{E}_{_}ₘ, the common line VCOM2, and the anode line ANO ₘ is a wiring for driving the display element 630.

In the case where a potential supplied to the signal line S_{E}_{_}ₙ and the signal line S_{E}_{_}ₙ₊₁ is different from a potential supplied to the signal line S_{L}_{_}ₙ and the signal line S_{L}_{_}ₙ₊₁, the signal line S_{E}_{_}ₙ and the signal line S_{L}_{_}ₙ₊₁ are preferably positioned apart from each other as shown in FIG. 13. In other words, the signal line S_{E}_{_}ₙ is preferably positioned adjacent to the signal line S_{L}_{_}ₙ₊₁. With this arrangement, an influence of the potential difference between the signal lines S_{L}_{_}ₙ and S_{L}_{_}ₙ₊₁ and signal lines S_{E}_{_}ₙ and S_{E}_{_}ₙ₊₁ can be reduced.

The display element 430 has a function of controlling transmission or reflection of light. In particular, the display element 430 is preferably a reflective display element which controls reflection of light. The display element 430 serving as a reflective display element can reduce power consumption of the display device because display can be performed with the use of external light. For example, the display element 430 may have a combined structure of a reflective film, a liquid crystal element, and a polarizing plate or a structure using micro electro mechanical systems (MEMS).

The display element 630 has a function of emitting light. Therefore, the display element 630 may be rephrased as a light-emitting element. For example, an electroluminescent element (also referred to as an EL element), or a light-emitting diode may be used as the display element 630.

As described above, in the display device of one embodiment of the present invention, display elements with different functions like the display elements 430 and 630 are used. In the case where a reflective liquid crystal element is used as one of the display elements and a transmissive EL element is used as the other of the display elements, a novel display device that is highly convenient or reliable can be provided. Furthermore, a display device with low power consumption and high display quality can be provided when a reflective liquid crystal element is used in an environment with bright external light and a transmissive EL element is used in an environment with weak external light.

Next, a method for driving the display element 430 and the display element 630 is described. Note that a structure including a liquid crystal element as the display element 430 and a light-emitting element as the display element 630 is used in the description below.

In the pixel circuit 501(m, n), a gate electrode of the transistor Tr1 is electrically connected to the scan line G_{L}_{_}ₘ. One of a source electrode and a drain electrode of the transistor Tr1 is electrically connected to the signal line S_{L}_{_}ₙ, and the other is electrically connected to one of a pair of electrodes of the display element 430. The transistor Tr1 has a function of controlling whether to write data of a data signal by being turned on or off.

The other of the pair of electrodes of the display element 430 is electrically connected to the common line VCOM1.

One of a pair of electrodes of the capacitor C1 is electrically connected to the common line COM ₘ, and the other of the pair of electrodes of the capacitor C1 is electrically connected to the other of the source electrode and the drain electrode of the transistor Tr1 and the one of the pair of electrodes of the display element 430. The capacitor C1 has a function of storing data written to the pixel circuit 501(m, n).

For example, the gate driver circuit portion 504b in FIG. 12 selects the pixel circuits 501(m, 1) to 501(m, Y) to turn on the transistor Tr1, and data of data signals are written. When the transistor Tr1 is turned off, the pixel circuit 501(m, n) to which the data has been written is brought into a holding state. This operation is sequentially performed row by row; thus, an image is displayed.

A gate electrode of the transistor Tr2 is electrically connected to the scan line G_{E}_{_}ₘ in the pixel circuit 501(m, n). One of a source electrode and a drain electrode of the transistor Tr2 is electrically connected to the signal line S_{E}_{_}ₙ and the other is electrically connected to a gate electrode of the transistor Tr3. The transistor Tr2 has a function of controlling whether to write data of a data signal by being turned on or off.

One of a pair of electrodes of the capacitor C2 is electrically connected to the anode line ANO ₘ. The other of the pair of electrodes of the capacitor C2 is electrically connected to the other of the source electrode and the drain electrode of the transistor Tr2. The capacitor C2 has a function of storing data written to the pixel circuit 501(m, n).

The gate electrode of the transistor Tr3 is electrically connected to the other of the source electrode and the drain electrode of the transistor Tr2. One of a source electrode and a drain electrode of the transistor Tr3 is electrically connected to the anode line ANO ₘ. The other of the source electrode and the drain electrode of the transistor Tr3 is electrically connected to one of a pair of electrodes of the display element 630. The transistor Tr3 includes a backgate electrode. The backgate electrode is electrically connected to the gate electrode of the transistor Tr3.

The other of the pair of electrodes of the display element 630 is electrically connected to the common line VCOM2.

For example, the gate driver circuit portion 504a in FIG. 12 selects the pixel circuits 501(m, 1) to 501(m, Y) to turn on the transistors Tr2, and data of data signals are written. When the transistor Tr2 is turned off, the pixel circuit 501(m, n) to which the data has been written is brought into a holding state. Furthermore, the amount of current flowing between the source electrode and the drain electrode of the transistor Tr3 is controlled in accordance with the potential of the written data signal. The display element 630 emits light with a luminance corresponding to the amount of flowing current. This operation is sequentially performed row by row; thus, an image is displayed.

In this manner, two display elements can be controlled separately with the use of different transistors in the display device of one embodiment of the present invention. Accordingly, a display device having high display quality can be provided.

It is preferable that transistors used in the display device of one embodiment of the present invention (the transistors Tr1, Tr2, and Tr3) each include a metal oxide. The transistor including a metal oxide can have relatively high field-effect mobility and thus can operate at high speed. The off-state current of the transistor including a metal oxide is extremely low. Therefore, the luminance of the display device can be maintained even when the refresh rate of the display device is lowered, so that power consumption can be lowered.

A progressive type display, an interlace type display, or the like can be employed as the display type of the display element 430 and the display element 630. Further, as color elements controlled in the pixel at the time of color display, three colors of R (red), G (green), and B (blue) can be given. Note that color elements are not limited to the three colors of R, G, and B. For example, one or more colors of yellow, cyan, magenta, white, and the like may be added to RGB. Further, the sizes of display regions may be different between respective dots of color elements. However, the display device of one embodiment of the present invention is not limited to a color display device and can be applied to a monochrome display device.

Here, the display regions of the display elements 430 and 630 in the pixel circuit 501(m, n) are described with reference to FIGS. 14A and 14B.

FIG. 14A is a schematic view illustrating display regions of the pixel circuit 501(m, n) and pixel circuits 501(m, n−1) and 501(m, n+1) which are adjacent to the pixel circuit 501(m, n) in the column direction.

The pixel circuit 501(m, n), the pixel circuit 501(m, n−1), and the pixel circuit 501(m, n+1) illustrated in FIG. 14A each include a display region 430d that functions as a display region of the display element 430 and a display region 630d that functions as a display region of the display element 630.

For example, the display region 430d includes a region which reflects light and the display region 630d includes a region which transmits light. Furthermore, as shown in FIG. 14A, the pixel circuit 501(m, n−1) and the pixel circuit 501(m, n+1) adjacent to the pixel circuit 501(m, n) in the column direction of the pixel circuit 501(m, n) each preferably include the display region 630d at a position different from the position of the display region 630d in the pixel circuit 501(m, n).

With the arrangement of the display regions 630d shown in FIG. 14A, the manufacturing yield in the case of separately forming the display elements 630 can be increased, or interference of light emitted from the display elements 630 between adjacent pixels can be suppressed.

Although an example where the pixel circuits 501(m, n−1), 501(m, n), and 501(m, n+1) are provided in a stripe arrangement in the column direction is shown in FIG. 14A, one embodiment of the present invention is not limited thereto. For example, a stripe arrangement in the row direction shown in FIG. 14B may be employed. Alternatively, although not illustrated, delta arrangement or pentile arrangement may be used. FIG. 14B is a schematic view illustrating display regions of the pixel circuit 501(m, n) and pixel circuits 501(m−1, n) and 501(m+1, n) which are adjacent to the pixel circuit 501(m, n) in the row direction of the pixel circuit 501(m, n).

The pixel circuit 501(m, n), the pixel circuit 501(m−1, n), and the pixel circuit 501(m+1, n) illustrated in FIG. 14B each include the display region 430d functioning as a display region of the display element 430 and the display region 630d functioning as a display region of the display element 630. The structures of the display regions 430d and 630d may be similar to those shown in FIG. 14A.

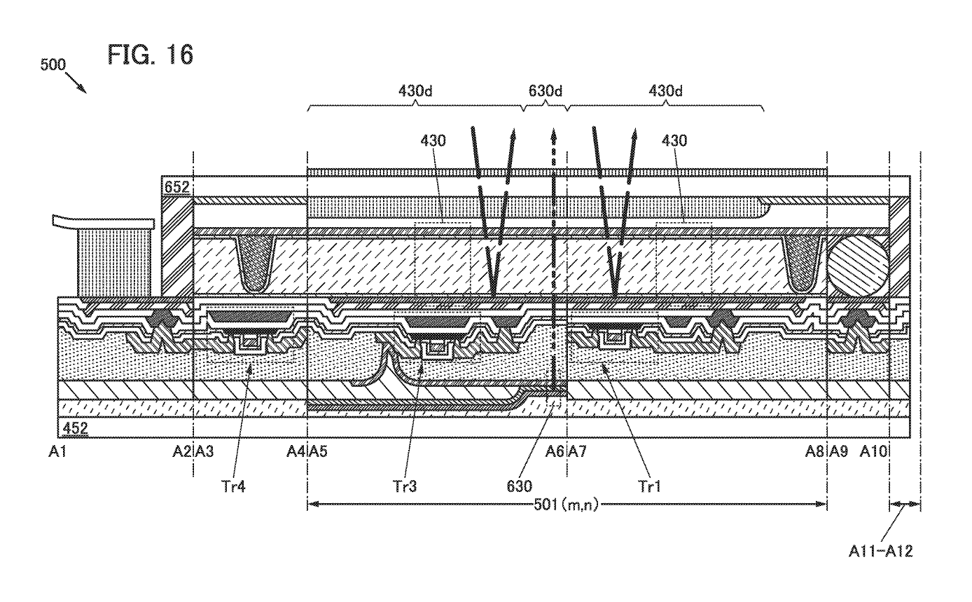

Next, a specific structure example of the display device 500 illustrated in FIG. 12 is described with reference to FIGS. 15A and 15B and FIG. 16.

FIG. 15A is a top view of the display device 500. As described above, the display device 500 includes the pixel portion 502, the gate driver circuit portions 504a and 504b and the source driver circuit portion 506 placed outside the pixel portion 502. FIG. 15A schematically illustrates the pixel circuit 501(m, n) included in the pixel portion 502. A flexible printed circuit (FPC) is electrically connected to the display device 500 in FIG. 15A.

FIG. 15B is a top view schematically illustrating the pixel circuit 501(m, n) shown in FIG. 15A and the pixel circuit 501(m, n+1) adjacent to the pixel circuit 501(m, n). The signal lines S_{L}_{_}ₙ, S_{L}_{_}ₙ₊₁, S_{E}_{_}ₙ, and S_{E}_{_}ₙ₊₁, the scan lines G_{L}_{_}ₘ and G_{E}_{_}ₘ, the common line COM ₘ, and the transistors Tr1, Tr2, and Tr3 in FIG. 15B respectively correspond to the reference numerals in FIG. 13. The display region 430d and the display region 630d in FIG. 15B correspond to the reference numerals in FIG. 14A. A common line COM ₘ₊₁ in FIG. 15B indicates a common line included in the pixel circuit 501(m+1, n) adjacent to the pixel circuit 501(m, n).

Next, a cross-sectional structure of the display device 500 is described with reference to FIG. 16.

FIG. 16 is a cross-sectional view corresponding to cross sections taken along dashed-dotted lines A1-A2, A3-A4, A5-A6, A7-A8, A9-A10, and A11-A12 illustrated in FIGS. 15A and 15B.

A cross section taken along dashed-dotted line A1-A2 corresponds to a region in which the FPC is attached to the display device 500. A cross section taken along dashed-dotted line A3-A4 corresponds to a region in which the gate driver circuit portion 504a is provided. A cross section taken along dashed-dotted line A5-A6 corresponds to a region in which the display element 430 and the display element 630 are provided. A cross section taken along dashed-dotted line A7-A8 corresponds to a region in which the display element 430 is provided. A cross section taken along dashed-dotted line A9-A10 corresponds to a connection region of the display device 500. A cross section taken along dashed-dotted line A11-A12 corresponds to the edge of the display device 500 and the vicinity thereof

In FIG. 16, the display device 500 includes the display element 430, the display element 630, the transistor Tr1, the transistor Tr3, and a transistor Tr4 between a substrate 452 and a substrate 652.

As described above, the display element 430 has a function of reflecting incident light, and the display element 630 has a function of emitting light. In FIG. 16, the light entering the display element 430 and the reflected light are schematically denoted by arrows of dashed lines. Furthermore, the light emitted from the display element 630 is schematically denoted by an arrow of a dashed double-dotted line.

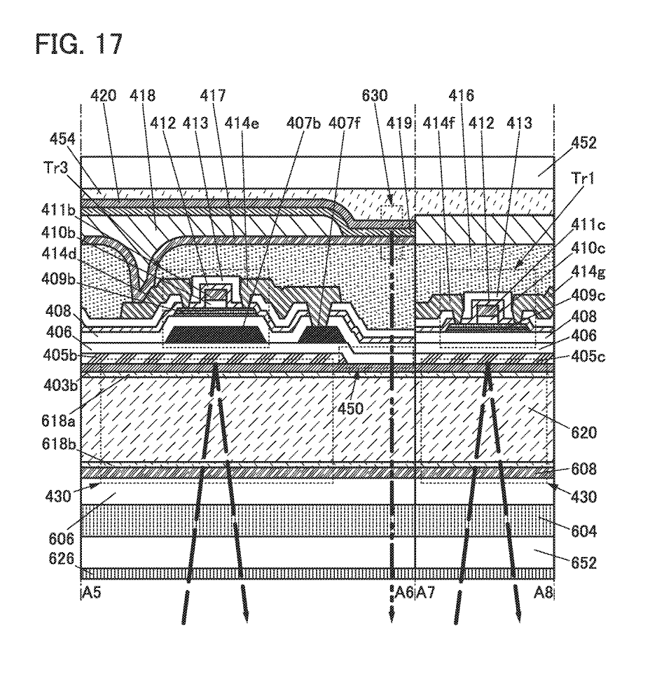

First, the cross-sections taken along dashed-dotted lines A5-A6 and A7-A8 in FIG. 16 are described in detail with reference to FIG. 17. FIG. 17 corresponds to an enlarged cross-sectional view of components taken along dashed-dotted lines A5-A6 and A7-A8 in FIG. 16. The enlarged cross-sectional view is reversed upside down. Note that in FIG. 17, some components are not illustrated in order to avoid complexity of the drawing.

The display element 430 includes a conductive film 403b, a liquid crystal layer 620, and a conductive film 608. The conductive film 403b functions as a pixel electrode, and the conductive film 608 functions as a counter electrode. The conductive film 403b is electrically connected to the transistor Tr1.

The display element 430 includes conductive films 405b and 405c electrically connected to the conductive film 403b. The conductive films 405b and 405c have a function of reflecting incident light. That is, the conductive films 405b and 405c function as reflective films. An opening 450 through which incident light passes is provided in the reflective films. In FIG. 17, a conductive film functioning as a reflective film is separated into island shapes by the opening 450, whereby the conductive film 405c is positioned below the transistor Tr1 and the conductive film 405b is positioned below the transistor Tr3. Since light emitted from the display element 630 is extracted through the opening 450, the opening 450 corresponds to the display region 630d illustrated in FIG. 16.

The display element 630 has a function of emitting light toward the opening 450. In FIG. 17, the display element 630 is what is called a bottom emission type light-emitting element.

The display element 630 includes a conductive film 417, an EL layer 419, and a conductive film 420. The conductive film 417 functions as a pixel electrode and an anode electrode. The conductive film 420 functions as a counter electrode and a cathode electrode. Although a description is made on a structure where the conductive film 417 functions as an anode electrode and the conductive film 420 functions as a cathode electrode in this embodiment, one embodiment of the present invention is not limited thereto. For example, the conductive film 417 may function as a cathode electrode, and the conductive film 420 may function as an anode electrode.

The conductive film 417 is electrically connected to the transistor Tr3.

The transistors Tr1 and Tr3 each include a metal oxide. The conductive films 403b and 417 functioning as pixel electrodes each contain at least one metal element contained in the metal oxide included in the transistors Tr1 and Tr3.

For example, in the case where a metal oxide is used in channel regions of the transistors Tr1 and Tr3 and a metal oxide having the same composition as the metal oxide which is used in the channel regions is used in the conductive films 403b and 417 functioning as pixel electrodes, manufacturing cost can be reduced. As illustrated in FIG. 17, since a plurality of insulating films, conductive films, semiconductor films, or the like are necessary in a display device including a plurality of display elements and a plurality of transistors, it is important to use the same material in different processes.

Each of the transistors Tr1 and Tr3 preferably has a staggered structure (also referred to as a top gate structure) as illustrated in FIG. 17. When the staggered structure is employed, parasitic capacitance that can be generated between a gate electrode and a source electrode and between the gate electrode and a drain electrode can be reduced.

The transistor Tr1 is formed over an insulating film 406 and an insulating film 408 and includes a metal oxide film 409c over the insulating film 408, an insulating film 410c over the metal oxide film 409c, and a metal oxide film 411c over the insulating film 410c. The insulating film 410c functions as a gate insulating film, and the metal oxide film 411c functions as a gate electrode.

Insulating films 412 and 413 are provided over the metal oxide films 409c and 411c. Openings reaching the metal oxide film 409c are provided in the insulating films 412 and 413, and conductive films 414f and 414g are electrically connected to the metal oxide film 409c through the openings. The conductive films 414f and 414g function as a source electrode and a drain electrode of the transistor Tr1.

Insulating films 416 and 418 are provided over the transistor Tr1.

The transistor Tr3 is formed over the insulating film 406, and includes a conductive film 407b over the insulating film 406, the insulating film 408 over the conductive film 407b, a metal oxide film 409b over the insulating film 408, an insulating film 410b over the metal oxide film 409b, and a metal oxide film 411b over the insulating film 410b. The conductive film 407b functions as a first gate electrode, and the insulating film 408 functions as a first gate insulating film. The insulating film 410b functions as a second gate insulating film, and the metal oxide film 411b functions as a second gate electrode.

The insulating films 412 and 413 are provided over the metal oxide films 409b and 411b. Openings reaching the metal oxide film 409b are provided in the insulating films 412 and 413, and conductive films 414d and 414e are electrically connected to the metal oxide film 409b through the openings. The conductive films 414d and 414e function as a source electrode and a drain electrode of the transistor Tr3.

The conductive film 414e is electrically connected to a conductive film 407f through an opening provided in the insulating films 408, 412, and 413. The conductive film 407f is formed through the same process as the conductive film 407b and functions as a connection electrode.

The insulating film 416 and the conductive film 417 are provided over the transistor Tr3. An opening reaching the conductive film 414d is provided in the insulating film 416, and the conductive film 414d and the conductive film 417 are electrically connected to each other through the opening.

The insulating film 418, the EL layer 419, and the conductive film 420 are provided over the conductive film 417. An opening reaching the conductive film 417 is provided in the insulating film 418, and the conductive film 417 and the EL layer 419 are electrically connected to each other through the opening.

The conductive film 420 is adhered to the substrate 452 with a sealing material 454 placed therebetween.

A coloring film 604, an insulating film 606, and the conductive film 608 are provided over the substrate 652 that faces the substrate 452. A functional film 626 is provided below the substrate 652. Light reflected by the display element 430 and light emitted from the display element 630 are extracted through the coloring film 604, the functional film 626, and the like.

The display element 430 includes alignment films 618a and 618b in contact with the liquid crystal layer 620 as illustrated in FIG. 17. Note that a structure without the alignment films 618a and 618b may be employed.

When the transistors Tr1 and Tr3 have different structures as illustrated in FIG. 17, the area of the circuit can be reduced. Specifically, the transistor Tr1 is a single-gate transistor in which the metal oxide film 411c functioning as a gate electrode is provided, whereas the transistor Tr3 is a multi-gate transistor in which the conductive film 407b functioning as a first gate electrode and the metal oxide film 411b functioning as a second gate electrode are provided. Note that the transistor structure that is used in the display device of one embodiment of the present invention is not limited to the above-described structure. For example, both the transistors Tr1 and Tr3 may have either a single-gate structure or a multi-gate structure.

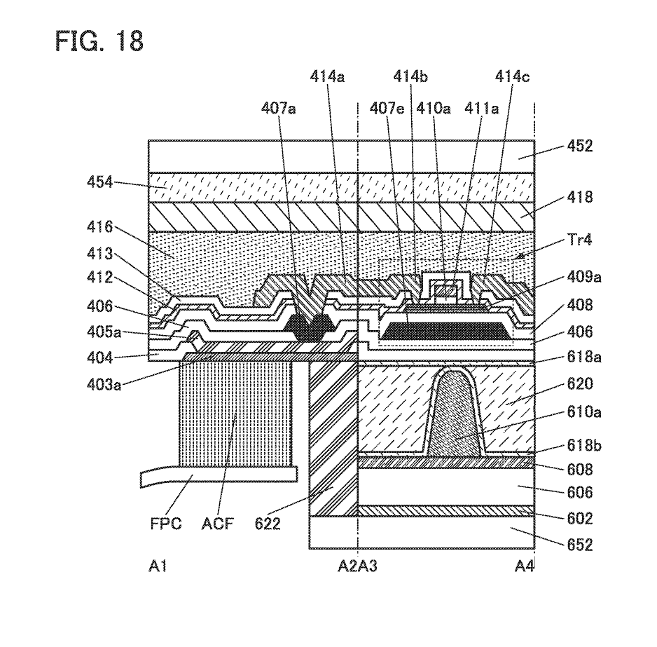

The cross-sections taken along dashed-dotted lines A1-A2 and A3-A4 in FIG. 16 are described in detail with reference to FIG. 18. FIG. 18 corresponds to an enlarged cross-sectional view of components taken along dashed-dotted lines A1-A2 and A3-A4 in FIG. 16. The enlarged cross-sectional view is reversed upside down. Note that in FIG. 18, some components are not illustrated in order to avoid complexity of the drawing.

The FPC illustrated in FIG. 18 is electrically connected to a conductive film 403a with an anisotropic conductive film (ACF) placed therebetween. An insulating film 404 is provided over the conductive film 403a. An opening reaching the conductive film 403a is provided in the insulating film 404, and the conductive film 403a and a conductive film 405a are electrically connected to each other through the opening.

The insulating film 406 is provided over the conductive film 405a. An opening reaching the conductive film 405a is provided in the insulating film 406, and the conductive film 405a and a conductive film 407a are electrically connected to each other through the opening. The insulating films 408, 412, and 413 are provided over the conductive film 407a. An opening reaching the conductive film 407a is provided in the insulating films 408, 412, and 413, and the conductive film 407a and a conductive film 414a are electrically connected to each other through the opening.

The insulating films 416 and 418 are provided over the insulating film 413 and the conductive film 414a. The insulating film 418 is adhered to the substrate 452 with the sealing material 454 placed therebetween.

The transistor Tr4 illustrated in FIG. 18 corresponds to a transistor included in the gate driver circuit portion 504a.

The transistor Tr4 is formed over the insulating film 406 and includes a conductive film 407e over the insulating film 406, the insulating film 408 over the conductive film 407e, a metal oxide film 409a over the insulating film 408, an insulating film 410a over the metal oxide film 409a, and a metal oxide film 411a over the insulating film 410a. The conductive film 407e functions as a first gate electrode. The insulating film 410a functions as a second gate insulating film, and the metal oxide film 411a functions as a second gate electrode.

The insulating films 412 and 413 are provided over the metal oxide films 409a and 411a. Openings reaching the metal oxide film 409a are provided in the insulating films 412 and 413, and conductive films 414b and 414c are electrically connected to the metal oxide film 409a through the openings. The conductive films 414b and 414c function as a source electrode and a drain electrode of the transistor Tr4.

The transistor Tr4 is a multi-gate transistor like the transistor Tr3 described above. A multi-gate transistor is preferably used in the gate driver circuit portion 504a because the current drive capability can be improved. Since the use of a multi-gate transistor can improve the current drive capability, the width of the driver circuit can be reduced.

The insulating films 416 and 418 are provided over the transistor Tr4. The insulating film 418 is adhered to the substrate 452 with the sealing material 454 placed therebetween.

A light-blocking film 602, the insulating film 606, and the conductive film 608 are provided over the substrate 652 that faces the substrate 452.

A structure body 610a is formed over the conductive film 608 in a position overlapping with the transistor Tr4. The structure body 610a has a function of controlling the thickness of the liquid crystal layer 620. The alignment films 618a and 618b are formed between the structure body 610a and the insulating film 404 in FIG. 18. Note that the alignment films 618a and 618b are not necessarily formed between the structure body 610a and the insulating film 404.

A sealant 622 is provided at an end portion of the substrate 652. Note that the sealant 622 is provided between the substrate 652 and the conductive film 403a.

Next, the components of the display device 500 illustrated in FIGS. 16 to 18 are described below.

The substrates 452 and 652 can be formed using a material having heat resistance high enough to withstand heat treatment in the manufacturing process.

Specifically, non-alkali glass, soda-lime glass, potash glass, crystal glass, quartz, sapphire, or the like can be used. Alternatively, an inorganic insulating film may be used. Examples of the inorganic insulating film include a silicon oxide film, a silicon nitride film, a silicon oxynitride film, and an alumina film.

The non-alkali glass may have a thickness of greater than or equal to 0.2 mm and less than or equal to 0.7 mm, for example. The non-alkali glass may be polished to obtain the above thickness.

For example, a large-sized glass substrate having any of the following sizes can be used as each of the substrates 452 and 652: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Alternatively, for the substrates 452 and 652, an organic material such as a resin, a resin film, or plastic may be used. Examples of the resin film include polyester, polyolefin, polyamide (e.g., nylon or aramid), polyimide, polycarbonate, polyurethane, an acrylic resin, an epoxy resin, polyethylene terephthalate (PET), polyethylene naphthalate (PEN), polyether sulfone (PES), and a resin having a siloxane bond. For the insulating films 404, 406, 408, 410a, 410b, 410c, 412, 413, 416, 418, and 606, an inorganic insulating material, an organic insulating material, or a composite insulating material including an inorganic insulating material and an organic insulating material can be used.

Examples of the inorganic insulating material include a silicon oxide film, a silicon nitride film, a silicon oxynitride film, a silicon nitride oxide film, and an aluminum oxide film. Alternatively, a plurality of the above inorganic materials may be stacked.

Examples of the above organic insulating material include materials that include polyester, polyolefin, polyamide (e.g., nylon or aramid), polyimide, polycarbonate, polyurethane, an acrylic-based resin, an epoxy-based resin, and a resin having a siloxane bond. As the organic insulating material, a photosensitive material may be used.

The metal oxide films 409a, 409b, and 409c have a multilayer structure, and a cloud-aligned composite OS (CAC-OS) may be used for at least one layer or all layers.

The CAC-OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of an oxide semiconductor, a state in which one or more metal elements are unevenly distributed and regions including the metal element(s) are mixed is referred to as a mosaic pattern or a patch-like pattern. The region has a size of greater than or equal to 0.5 nm and less than or equal to 10 nm, preferably greater than or equal to 1 nm and less than or equal to 2 nm, or a similar size.

Note that an oxide semiconductor preferably contains at least indium. In particular, indium and zinc are preferably contained. In addition, aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0), gallium zinc oxide (Ga_{X4}Zn_{Y4}O_{Z4}, where X4, Y4, and Z4 are real numbers greater than 0), or the like, and a mosaic pattern is formed. Then, InO_{X1} or In_{X2}Zn_{Y2}O_{Z2} forming the mosaic pattern is evenly distributed in the film. This composition is also referred to as a cloud-like composition.

That is, the CAC-OS is a composite oxide semiconductor with a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is greater than the atomic ratio of In to the element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In(₁₊ₓ₀)Ga(₁₋ₓ₀)O₃(ZnO)ₘ₀ (−1≦x0≦1; m0 is a given number).

The above crystalline compounds have a single crystal structure, a polycrystalline structure, or a c-axis-aligned crystalline (CAAC) structure. Note that the CAAC structure is a crystal structure in which a plurality of IGZO nanocrystals have c-axis alignment and are connected in the a-b plane direction without alignment.

On the other hand, the CAC-OS relates to the material composition of an oxide semiconductor. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected metal element(s) as a main component(s) are observed in part of the CAC-OS and nanoparticle regions including In as a main component are observed in part thereof, and these nanoparticle regions are randomly dispersed to form a mosaic pattern in the CAC-OS.

The CAC-OS can be formed by a sputtering method under conditions where a substrate is not heated intentionally, for example. In the case of forming the CAC-OS by a sputtering method, one or more selected from an inert gas (typically, argon), an oxygen gas, and a nitrogen gas may be used as a deposition gas. The ratio of the flow rate of an oxygen gas to the total flow rate of the deposition gas at the time of deposition is preferably as low as possible, and for example, the flow ratio of an oxygen gas is preferably higher than or equal to 0% and less than 30%, further preferably higher than or equal to 0% and less than or equal to 10%.

The CAC-OS is characterized in that no clear peak is observed in measurement using θ/2θ scan by an out-of-plane method, which is an X-ray diffraction (XRD) measurement method. That is, X-ray diffraction shows no alignment in the a-b plane direction and the c-axis direction in a measured region.

In an electron diffraction pattern of the CAC-OS which is obtained by irradiation with an electron beam with a probe diameter of 1 nm (also referred to as a nanometer-sized electron beam), a ring-like region with high luminance and a plurality of bright spots in the ring-like region are observed. Therefore, the electron diffraction pattern indicates that the crystal structure of the CAC-OS includes a nanocrystal (nc) structure with no alignment in plan-view and cross-sectional directions.

For example, an energy dispersive X-ray spectroscopy (EDX) mapping image confirms that an In—Ga—Zn oxide with the CAC composition has a structure in which a region including GaO_{X3} as a main component and a region including In_{X2}Zn_{Y2}O_{Z2} or InO_{X1} are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby high on-state current (Iₒₙ) and high field-effect mobility (μ) can be achieved.

A semiconductor element including a CAC-OS has high reliability. Thus, the CAC-OS is suitably used in a variety of semiconductor devices typified by a display.

In this embodiment, the metal oxide films 409a, 409b, and 409c have a multilayer structure, and a CAC-OS may be used for at least one layer or all layers. Since the oxide semiconductor film has a multilayer structure, a plurality of kinds of CAC-OS layers with different atomic ratios can be stacked.

As examples of the liquid crystal layer 620, thermotropic liquid crystal, low-molecular liquid crystal, high-molecular liquid crystal, polymer dispersed liquid crystal, ferroelectric liquid crystal, and anti-ferroelectric liquid crystal are given. Alternatively, a liquid crystal material which exhibits a cholesteric phase, a smectic phase, a cubic phase, a chiral nematic phase, an isotropic phase, or the like may be used. Furthermore, a liquid crystal material exhibiting a blue phase may be used.

For a driving method of the liquid crystal layer 620, an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like can be used. In addition, the liquid crystal layer 620 can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

The EL layer 419 includes at least a light-emitting material. Examples of the light-emitting material include an organic compound and an inorganic compound such as a quantum dot.

The organic compound and the inorganic compound can be formed by an evaporation method (including a vacuum evaporation method), an ink-jet method, a coating method, or gravure printing, for example.

Examples of materials that can be used for the organic compound include a fluorescent material and a phosphorescent material. A fluorescent material is preferably used in terms of the lifetime, while a phosphorescent material is preferably used in terms of the efficiency. Furthermore, both a fluorescent material and a phosphorescent material may be used.

A quantum dot is a semiconductor nanocrystal with a size of several nanometers and contains approximately 1×10³ to 1×10⁶ atoms. Since energy shift of quantum dots depends on their size, quantum dots made of the same substance emit light with different wavelengths depending on their size; thus, emission wavelengths can be easily adjusted by changing the size of quantum dots.

Since a quantum dot has an emission spectrum with a narrow peak, emission with high color purity can be obtained. In addition, a quantum dot is said to have a theoretical internal quantum efficiency of approximately 100%, which far exceeds that of a fluorescent organic compound, i.e., 25%, and is comparable to that of a phosphorescent organic compound. Therefore, a quantum dot can be used as a light-emitting material to obtain a light-emitting element having high emission efficiency. Furthermore, since a quantum dot which is an inorganic compound has high inherent stability, a light-emitting element which is favorable also in terms of lifetime can be obtained.

Examples of a material of a quantum dot include a Group 14 element in the periodic table, a Group 15 element in the periodic table, a Group 16 element in the periodic table, a compound of a plurality of Group 14 elements in the periodic table, a compound of an element belonging to any of Groups 4 to 14 in the periodic table and a

Group 16 element in the periodic table, a compound of a Group 2 element in the periodic table and a Group 16 element in the periodic table, a compound of a Group 13 element in the periodic table and a Group 15 element in the periodic table, a compound of a Group 13 element in the periodic table and a Group 17 element in the periodic table, a compound of a Group 14 element in the periodic table and a Group 15 element in the periodic table, a compound of a Group 11 element in the periodic table and a Group 17 element in the periodic table, iron oxides, titanium oxides, spinel chalcogenides, and semiconductor clusters.

Specific examples include, but are not limited to, cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; triiron tetraoxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot, whose composition is represented by a given ratio, may be used. For example, an alloyed quantum dot of a compound of cadmium, selenium, and sulfur is a means effective in obtaining blue light because the emission wavelength can be changed by changing the content ratio of elements.

As the quantum dot, any of a core-type quantum dot, a core-shell quantum dot, a core-multishell quantum dot, and the like can be used. Note that when a core is covered with a shell formed of another inorganic material having a wider band gap, the influence of defects and dangling bonds existing at the surface of a nanocrystal can be reduced. Since such a structure can significantly improve the quantum efficiency of light emission, it is preferable to use a core-shell or core-multishell quantum dot. Examples of the material of a shell include zinc sulfide and zinc oxide.

Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability. Examples of the protective agent (or the protective group) include polyoxyethylene alkyl ethers such as polyoxyethylene lauryl ether, polyoxyethylene stearyl ether, and polyoxyethylene oleyl ether; trialkylphosphines such as tripropylphosphine, tributylphosphine, trihexylphosphine, and trioctylphoshine; polyoxyethylene alkylphenyl ethers such as polyoxyethylene n-octylphenyl ether and polyoxyethylene n-nonylphenyl ether; tertiary amines such as tri(n-hexyl)amine, tri(n-octyl)amine, and tri(n-decyl)amine; organophosphorus compounds such as tripropylphosphine oxide, tributylphosphine oxide, trihexylphosphine oxide, trioctylphosphine oxide, and tridecylphosphine oxide; polyethylene glycol diesters such as polyethylene glycol dilaurate and polyethylene glycol distearate; organic nitrogen compounds such as nitrogen-containing aromatic compounds, e.g., pyridines, lutidines, collidines, and quinolines; aminoalkanes such as hexylamine, octylamine, decylamine, dodecylamine, tetradecylamine, hexadecylamine, and octadecylamine; dialkylsulfides such as dibutylsulfide; dialkylsulfoxides such as dimethylsulfoxide and dibutylsulfoxide; organic sulfur compounds such as sulfur-containing aromatic compounds, e.g., thiophenes; higher fatty acids such as a palmitin acid, a stearic acid, and an oleic acid; alcohols; sorbitan fatty acid esters; fatty acid modified polyesters; tertiary amine modified polyurethanes; and polyethyleneimines.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength region of a spectrum of an ultraviolet region, a visible light region, and an infrared region by changing the size of quantum dots. The range of size (diameter) of quantum dots which is usually used is 0.5 nm to 20 nm, preferably 1 nm to 10 nm. The emission spectra are narrowed as the size distribution of the quantum dots gets smaller, and thus light can be obtained with high color purity.

The shape of the quantum dots is not particularly limited and may be a spherical shape, a rod shape, a circular shape, or the like. Quantum rods which are rod-like shape quantum dots emit directional light polarized in the c-axis direction; thus, quantum rods can be used as a light-emitting material to obtain a light-emitting element with higher external quantum efficiency.

In most EL elements, to improve emission efficiency, light-emitting materials are dispersed in host materials and the host materials need to be substances each having a singlet excitation energy or a triplet excitation energy higher than or equal to that of the light-emitting material. In the case of using a blue phosphorescent material, it is particularly difficult to develop a host material which has a triplet excitation energy higher than or equal to that of the blue phosphorescent material and which is excellent in terms of a lifetime. On the other hand, even when a light-emitting layer is composed of quantum dots and made without a host material, the quantum dots enable emission efficiency to be ensured; thus, a light-emitting element which is favorable in terms of a lifetime can be obtained. In the case where the light-emitting layer is composed of quantum dots, the quantum dots preferably have core-shell structures (including core-multishell structures).

For the alignment films 618a and 618b, a material containing polyimide or the like can be used. For example, a material containing polyimide or the like may be subjected to a rubbing process or an optical alignment process to have alignment in a predetermined direction.

The light-blocking film 602 functions as a black matrix. For the light-blocking film 602, a material that prevents light transmission is used. Examples of the material that prevents light transmission include a metal material and an organic resin material containing a black pigment.

The coloring film 604 functions as a color filter. For the coloring film 604, a material transmitting light of a predetermined color (e.g., a material transmitting light of blue, green, red, yellow, or white) is used.

The structure body 610a has a function of providing a certain space between components between which the structure body 610a is interposed. For the structure body 610a, an organic material, an inorganic material, or a composite material of an organic material and an inorganic material can be used. For the inorganic material and the organic material, the materials for the insulating films 404, 406, 408, 410a, 410b, 410c, 412, 413, 416, 418, and 606 can be used.

As the functional film 626, a polarizing plate, a retardation plate, a diffusing film, an anti-reflective film, a condensing film, or the like can be used. As the functional film 626, an antistatic film preventing the attachment of a foreign substance, a water repellent film suppressing the attachment of stain, a hard coat film suppressing generation of a scratch in use, or the like may be used.

For the sealing material 454, an inorganic material, an organic material, a composite material of an inorganic material and an organic material, or the like can be used. Examples of the organic material include a thermally fusible resin and a curable resin. As the sealing material 454, an adhesive including a resin material (e.g., a reactive curable adhesive, a photocurable adhesive, a thermosetting adhesive, or an anaerobic adhesive) may be used. Examples of such resin materials include an epoxy-based resin, an acrylic-based resin, a silicone-based resin, a phenol-based resin, a polyimide-based resin, an imide-based resin, a polyvinyl chloride (PVC) based resin, a polyvinyl butyral (PVB) based resin, and an ethylene vinyl acetate (EVA) based resin.

For the sealant 622, the materials for the sealing material 454 can be used. For the sealant 622, a material such as glass frit may be used in addition to the above materials. As a material used for the sealant 622, a material which is impermeable to moisture or oxygen is preferably used.

As described above, the display device of one embodiment of the present invention includes two display elements. Furthermore, the display device includes two transistors for driving the two display elements. A reflective liquid crystal element is used as one of the display elements and a transmissive EL element is used as the other of the display elements; thus, a novel display device that is highly convenient or reliable can be provided. With use of metal oxide films for channel regions of the transistors for driving the display elements and one electrode of each of the two display elements, a novel display device with low manufacturing cost can be provided. In addition, when each of the transistors has a staggered structure, parasitic capacitance generated between the gate electrode and the source and drain electrodes can be reduced, whereby a novel display device with low power consumption can be provided.

Note that the structure described in this embodiment can be combined with any of the structures described in the other embodiments as appropriate.

### Embodiment 5

In this embodiment, a portable information terminal 6000 including a display module of one embodiment of the present invention will be described.

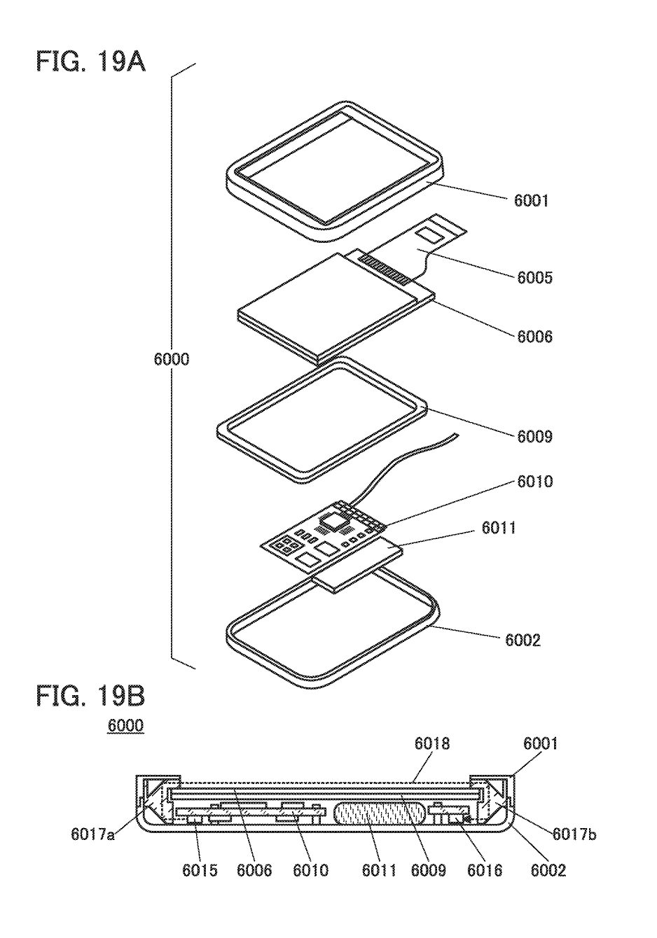

In the portable information terminal 6000 including a display module in FIG. 19A, a display panel 6006 connected to an FPC 6005, a frame 6009, a printed circuit board 6010, and a battery 6011 are provided between an upper cover 6001 and a lower cover 6002.

For example, the above-described display device manufactured using one embodiment of the present invention can be used for the display panel 6006. Thus, the portable information terminal can be manufactured with high yield.

The shapes and sizes of the upper cover 6001 and the lower cover 6002 can be changed as appropriate in accordance with the sizes of the display panel 6006.

A touch panel may be provided so as to overlap with the display panel 6006. The touch panel can be a resistive touch panel or a capacitive touch panel and may be formed to overlap with the display panel 6006. Instead of providing the touch panel, the display panel 6006 can have a touch panel function.

The frame 6009 protects the display panel 6006 and also serves as an electromagnetic shield for blocking electromagnetic waves generated by the operation of the printed circuit board 6010. The frame 6009 may serve as a radiator plate.

The printed circuit board 6010 has a power supply circuit and a signal processing circuit for outputting a video signal and a clock signal. As a power source for supplying power to the power supply circuit, an external commercial power source or the battery 6011 provided separately may be used. The battery 6011 can be omitted in the case of using a commercial power source.

The portable information terminal 6000 including the display module can be additionally provided with a member such as a polarizing plate, a retardation plate, or a prism sheet.

FIG. 19B is a cross-sectional schematic view of the portable information terminal 6000 including a display module with an optical touch sensor.

The portable information terminal 6000 including the display module includes a light-emitting portion 6015 and a light-receiving portion 6016 provided on the printed circuit board 6010. A pair of light guide portions (a light guide portion 6017a and a light guide portion 6017b) is provided in a region surrounded by the upper cover 6001 and the lower cover 6002.

For example, a plastic or the like can be used for the upper cover 6001 and the lower cover 6002. The upper cover 6001 and the lower cover 6002 can each be thin (e.g., more than or equal to 0.5 mm and less than or equal to 5 mm). In that case, the portable information terminal 6000 including the display module can be significantly lightweight. In addition, the upper cover 6001 and the lower cover 6002 can be manufactured with a small amount of material, and therefore, manufacturing cost can be reduced.

The display panel 6006 overlaps with the printed circuit board 6010 and the battery 6011 with the frame 6009 located therebetween. As the battery 6011, a laminated thin storage battery is used. The display panel 6006 and the frame 6009 are fixed to the light guide portion 6017a and the light guide portion 6017b.

Light 6018 emitted from the light-emitting portion 6015 travels over the display panel 6006 through the light guide portion 6017a and reaches the light-receiving portion 6016 through the light guide portion 6017b. For example, blocking of the light 6018 by a sensing target such as a finger or a stylus can be detected as touch operation.

A plurality of light-emitting portions 6015 are provided along two adjacent sides of the display panel 6006, for example. A plurality of light-receiving portions 6016 are provided so as to face the light-emitting portions 6015. Accordingly, information about the position of touch operation can be obtained.

As the light-emitting portion 6015, a light source such as an LED element can be used. It is particularly preferable to use a light source that emits infrared light, which is not visually recognized by users and is harmless to users, as the light-emitting portion 6015.

As the light-receiving portion 6016, a photoelectric element that receives light emitted by the light-emitting portion 6015 and converts it into an electrical signal can be used. A photodiode that can receive infrared light can be favorably used.

For the light guide portions 6017a and 6017b, members that transmit at least the light 6018 can be used. With the use of the light guide portions 6017a and 6017b, the light-emitting portion 6015 and the light-receiving portion 6016 can be placed under the display panel 6006, and a malfunction of the touch sensor due to external light reaching the light-receiving portion 6016 can be suppressed. It is particularly preferable to use a resin which absorbs visible light and transmits infrared light. This is more effective in suppressing the malfunction of the touch sensor.

### Embodiment 6

In this embodiment, examples of electronic devices that use the display device of one embodiment of the present invention will be described.

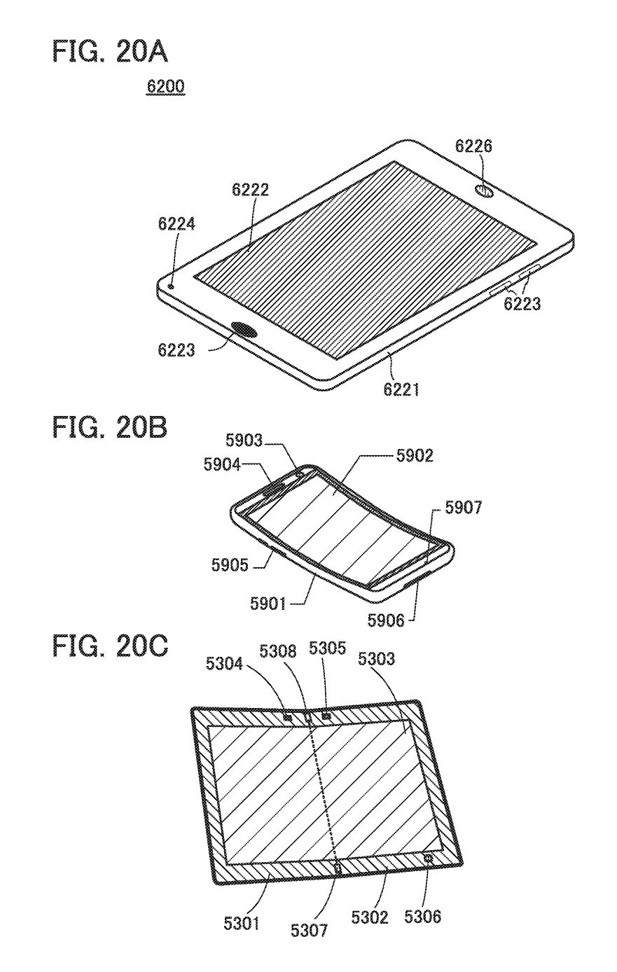

FIG. 20A illustrates an example of an electronic device that uses the display device of one embodiment of the present invention. FIG. 20A illustrates a tablet information terminal 6200, which includes a housing 6221, a display device 6222, operation buttons 6223, and a speaker 6224. A position input function may be added to the display device 6222 of one embodiment of the present invention.

The position input function can be added by providing a touch panel in the display device. Alternatively, the position input function can be added by providing a photoelectric conversion element called a photosensor in a pixel portion of the display device. As the operation buttons 6223, any one of a power switch for starting the information terminal 6200, a button for operating an application of the information terminal 6200, a volume control button, a switch for turning on or off the display device 6222, and the like can be provided. Although the number of the operation buttons 6223 is three in the information terminal 6200 illustrated in FIG. 20A, the number and position of operation buttons included in the information terminal 6200 is not limited to this example. Low power consumption can be achieved with the use of the display device 6222 of one embodiment of the present invention in the information terminal 6200.

Although not illustrated, the information terminal 6200 illustrated in FIG. 20A may include a sensor (which measures force, displacement, position, speed, acceleration, angular velocity, rotational frequency, distance, light, liquid, magnetism, temperature, a chemical substance, a sound, time, hardness, electric field, current, voltage, electric power, radiation, flow rate, humidity, gradient, oscillation, smell, infrared rays, or the like) inside the housing 6221. In particular, when a measuring device including a sensor such as a gyroscope or an acceleration sensor for measuring inclination is provided, display on the screen of the display device 6222 can be automatically changed in accordance with the orientation of the information terminal 6200 illustrated in FIG. 20A by determining the orientation of the information terminal 6200 (the orientation of the information terminal with respect to the vertical direction).

A combination of information about the inclination of the housing 6221 with information about the incident angle and illuminance of external light which is obtained from an optical sensor enables more accurate adjustments of the color and gradation of image data to be displayed by the display device 6222. In that case, with an imaging sensor provided in the housing 6221, information about the position of user's eyes (or viewing direction) with respect to the information terminal 6200 is obtained and combined with information about the inclination of the housing 6221 and the incident angle and illuminance of external light. This enables even more accurate adjustments of the color and gradation of an image to be displayed by the display device 6222.

Although not illustrated, the information terminal 6200 illustrated in FIG. 20A may include a microphone in addition to the speaker. With this structure, the information terminal 6200 can have a telephone function like a cellular phone, for example. Furthermore, the information terminal 6200 preferably includes a camera 6226 as illustrated in FIG. 20A. Although not illustrated, the information terminal 6200 illustrated in FIG. 20A may include a light-emitting device for use as a flashlight or a lighting device.

Although not illustrated, the information terminal 6200 illustrated in FIG. 20A may include a device for obtaining biological information such as fingerprints, veins, iris, voice prints, or the like. With this structure, the information terminal 6200 can have a biometric identification function.

In some cases, the information terminal 6200 illustrated in FIG. 20A can have a speech interpretation function. With the speech interpretation function, the information terminal 6200 can have a function of operating the information terminal 6200 by speech recognition, a function of interpreting a speech or a conversation and creating a summary of the speech or the conversation, and the like. This can be utilized to create meeting minutes or the like, for example.

FIG. 20B illustrates a cellular phone, which includes a display device 5902 of one embodiment of the present invention, a microphone 5907, a speaker 5904, a camera 5903, an external connection portion 5906, and an operation button 5905 in a housing 5901 having a curved surface. Low power consumption can be achieved with the use of the display device 5902 of one embodiment of the present invention in the cellular phone.

FIG. 20C illustrates a tablet personal computer, which includes a housing 5301, a housing 5302, a display device 5303 of one embodiment of the present invention, an optical sensor 5304, an optical sensor 5305, a switch 5306, and the like. The display device 5303 is supported by the housing 5301 and the housing 5302. The display device 5303 is formed using a flexible substrate and therefore has a function of being flexible in shape and bendable. By changing the angle between the housing 5301 and the housing 5302 with a hinge 5307 and a hinge 5308, the display device 5303 can be folded such that the housing 5301 and the housing 5302 overlap with each other. Although not illustrated, an open/close sensor may be incorporated so that the above-described angle change can be used as information about conditions of use of the display device 5303. The optical sensor 5304 is provided on the housing 5301, and the optical sensor 5305 is provided on the housing 5302. With this structure, both information about the angle of incidence of external light on the display device 5303 in a region supported by the housing 5301 and information about the angle of incidence of external light on the display device 5303 in a region supported by the housing 5302 can be used as information about conditions of use of the display device 5303. Low power consumption can be achieved with the use of the display device 5303 of one embodiment of the present invention in the tablet personal computer.

This embodiment can be implemented in appropriate combinations with any of the other embodiments.

This application is based on Japanese Patent Application serial no. 2016-137191 filed with Japan Patent Office on Jul. 11, 2016, the entire contents of which are hereby incorporated by reference.

What is claimed is:

1. A semiconductor device comprising a transistor, the transistor comprising:
a first metal oxide layer;
a second metal oxide layer; and
a third metal oxide layer,
wherein the first metal oxide layer, the second metal oxide layer, and the third metal oxide layer are stacked,
wherein the second metal oxide layer is between the first metal oxide layer and the third metal oxide layer,
wherein a conduction band minimum of the second metal oxide layer is at a lower energy level than a conduction band minimum of the first metal oxide layer and a conduction band minimum of the third metal oxide layer, and
wherein a side surface of the second metal oxide layer is in contact with a source electrode or a drain electrode.

2. The semiconductor device according to claim 1,
wherein the first metal oxide layer and the third metal oxide layer each comprise an M1 oxide, an In—M1—Zn oxide, or an In-M1-M2-Zn oxide, wherein M1 is one kind or a plurality of kinds selected from Al, Ga, Si, Mg, Zr, Be, and B, and
wherein M2 is one kind or a plurality of kinds selected from Ti, Ge, Sn, V, Ni, Mo, W, and Ta.

3. The semiconductor device according to claim 1, wherein the second metal oxide layer comprises an In oxide, an In—Zn oxide, an In-M2 oxide, or an In-M2-Zn oxide.

4. The semiconductor device according to claim 2, wherein the second metal oxide layer comprises an In oxide, an In—Zn oxide, an In-M2 oxide, or an In-M2-Zn oxide.

5. The semiconductor device according to claim 1, further comprising:
a first gate electrode; and
a second gate electrode,
wherein the first to the third metal oxide layers are between the first gate electrode and the second gate electrode.

6. The semiconductor device according to claim 2, further comprising:
a first gate electrode; and
a second gate electrode,
wherein the first to the third metal oxide layers are between the first gate electrode and the second gate electrode.

7. A semiconductor device comprising:
a first metal oxide layer;
a second metal oxide layer;
a third metal oxide layer;
a fourth metal oxide layer; and
a fifth metal oxide layer,
wherein the first to the fifth metal oxide layers are stacked in this order,
wherein the third metal oxide layer has a conduction band minimum at a lower energy level than a conduction band minimum of each of the second metal oxide layer and the fourth metal oxide layer, and
wherein each of the second metal oxide layer and the fourth metal oxide layer has the conduction band minimum at a lower energy level than a conduction band minimum of each of the first metal oxide layer and the fifth metal oxide layer.

8. The semiconductor device according to claim 7,
wherein the first metal oxide layer and the fifth metal oxide layer comprise the same material that is an M1 oxide, an In-M1-Zn oxide, or an In-M1-M2-Zn oxide,
wherein M1 is one kind or a plurality of kinds selected from Al, Ga, Si, Mg, Zr, Be, and B, and
wherein M2 is one kind or a plurality of kinds selected from Ti, Ge, Sn, V, Ni, Mo, W, and Ta.

9. The semiconductor device according to claim 8, wherein the second metal oxide layer and the fourth metal oxide layer comprise the same material that is an In oxide, an In—Zn oxide, an In-M2 oxide, or an In-M2-Zn oxide.

10. The semiconductor device according to claim 8,
wherein the third metal oxide layer comprises a material that is different from a material of the first metal oxide layer and that is another M1 oxide, another In-M1-Zn oxide, or another In-M1-M2-Zn oxide,
wherein M1 in the third metal oxide layer is one kind or a plurality of kinds selected from Al, Ga, Si, Mg, Zr, Be, and B, and
wherein M2 in the third metal oxide layer is one kind or a plurality of kinds selected from Ti, Ge, Sn, V, Ni, Mo, W, and Ta.

11. The semiconductor device according to claim 7, wherein the second metal oxide layer and the fourth metal oxide layer comprise the same material that is an In oxide, an In—Zn oxide, an In-M2 oxide, or an In-M2-Zn oxide.

12. The semiconductor device according to claim 7,
wherein the third metal oxide layer comprises a material that is different from a material of the first metal oxide layer and that is an M1 oxide, an In-M1-Zn oxide, or an In-M1-M2-Zn oxide,
wherein M1 is one kind or a plurality of kinds selected from Al, Ga, Si, Mg, Zr, Be, and B, and
wherein M2 is one kind or a plurality of kinds selected from Ti, Ge, Sn, V, Ni, Mo, W, and Ta.

13. The semiconductor device according to claim 1, wherein a thickness of the first metal oxide layer is more than or equal to 0.1 nm and less than 30 nm, more than or equal to 0.1 nm and less than or equal to 10 nm, or more than or equal to 0.1 nm and less than or equal to 3 nm.

14. The semiconductor device according to claim 2, wherein a thickness of the first metal oxide layer is more than or equal to 0.1 nm and less than 30 nm, more than or equal to 0.1 nm and less than or equal to 10 nm, or more than or equal to 0.1 nm and less than or equal to 3 nm.

15. The semiconductor device according to claim 7, wherein a thickness of the first metal oxide layer is more than or equal to 0.1 nm and less than 30 nm, more than or equal to 0.1 nm and less than or equal to 10 nm, or more than or equal to 0.1 nm and less than or equal to 3 nm.

16. The semiconductor device according to claim 8, wherein a thickness of the first metal oxide layer is more than or equal to 0.1 nm and less than 30 nm, more than or equal to 0.1 nm and less than or equal to 10 nm, or more than or equal to 0.1 nm and less than or equal to 3 nm.
